(19) United States
(12) Patent Application Publication
(10) Pub. No.: US 2024/0301283 A1
(43) Pub. Date: Sep. 12, 2024

(54) QUANTUM DOT COMPLEX, METHOD FOR PREPARING THE QUANTUM DOT COMPLEX, AND DISPLAY DEVICE COMPRISING THE QUANTUM DOT COMPLEX

(71) Applicant: Samsung Display Co., Ltd., Yongin-si (KR)

(72) Inventors: KAWON PAK, Yongin-si (KR); JUO NAM, Yongin-si (KR); KYUNGSIG LEE, Yongin-si (KR); SEUNGHEE JANG, Yongin-si (KR); JAEBOK CHANG, Yongin-si (KR)

(73) Assignee: Samsung Display Co., Ltd., Yongin-si (KR)

(21) Appl. No.: 18/529,005

(22) Filed: Dec. 5, 2023

(30) Foreign Application Priority Data
Jan. 6, 2023 (KR) 10-2023-0002242

(51) Int. Cl. C09K 11/06; B82Y 20/00; B82Y 40/00; C09K 11/02; H10K 50/115; H10K 59/38

(52) U.S. Cl. CPC C09K 11/06; C09K 11/025; H10K 50/115; H10K 59/38; B82Y 20/00; B82Y 40/00; C09K 2211/10; C09K 2211/14

(57) ABSTRACT

Embodiments provide a quantum dot complex including a quantum dot, a ligand which is bonded on the surface of the quantum dot and contains a hydrophilic group, and a protective layer which is bonded on the surface of the quantum dot and contains an aluminum oxide. Embodiments also provide a display device which includes the quantum dot complex.

### CROSS-REFERENCE TO RELATED APPLICATION(S)

This application claims priority to and benefits of Korean Patent Application No. 10-2023-0002242 under 35 U.S.C. § 119, filed on Jan. 6, 2023, in the Korean Intellectual Property Office, the entire contents of which are incorporated herein by reference.

### BACKGROUND

### 1. Technical Field

The disclosure relates to a quantum dot complex, a method for preparing the quantum dot complex, and a display device including the quantum dot complex.

### 2. Description of the Related Art

Various display devices used in multimedia devices such as televisions, mobile phones, tablet computers, navigation devices, and game consoles are being developed. These display devices include a display module containing a so-called self-luminescent light emitting element in which a luminescent material emits light to implement display.

In order to improve color reproducibility of the display device, the display module may include different types of light control layers according to pixels. The light control layer may transmit only a portion of source light in a wavelength range or may change the wavelength range of the source light. Development on a light emitting element using quantum dots as a luminescent material is underway, and there is a demand for improving the luminous efficiency and high color characteristics of the light emitting element using quantum dots.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a quantum dot complex exhibiting a high quantum yield and excellent stability.

Embodiments also provide a method for preparing the quantum dot complex exhibiting a high quantum yield and excellent stability.

The disclosure also provides a display device including the quantum dot complex and having improved luminous efficiency.

An embodiment provides a quantum dot complex which may include a quantum dot, a ligand which is bonded on the surface of the quantum dot and includes a hydrophilic group, and a protective layer which is bonded on the surface of the quantum dot and includes an aluminum oxide.

In an embodiment, the hydrophilic group may be a polyethylene glycol group or a (meth)acrylate group.

In an embodiment, the ligand may include a first head part bonded on the surface of the quantum dot, a first linking part which is linked to the first head part, and a first tail part linked to the first linking part; and at least one of the first linking part and the first tail part may include the hydrophilic group.

In an embodiment, the first head part may be a thiol group, a dithioic acid group, a phosphine group, a catechol group, an amine group, or a carboxylic acid group.

In an embodiment, the ligand may be a monodentate ligand or a bidentate ligand.

In an embodiment, the ligand may be represented by Formula 1-1 or Formula 1-2.

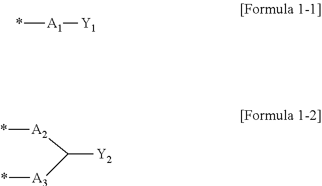

In Formula 1-1 and Formula 1-2, A to A₃ may each independently be O, S, or NH; Y₁ and Y₂ may each independently be a moiety represented by one of Formula 2-1 to Formula 2-3; and *---- is a position linked on the surface of the quantum dot:

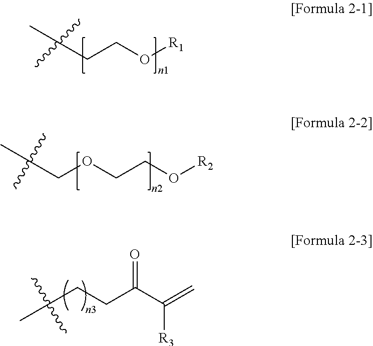

In Formula 2-1 to Formula 2-3, R₁ and R₂ may each independently be a substituted or unsubstituted oxy group, a substituted or unsubstituted thiol group, a substituted or unsubstituted alkyl group having 1 to 20 carbon atoms, or a substituted or unsubstituted alkenyl group having 2 to 20 carbon atoms; R₃ may be a hydrogen atom, or a substituted or unsubstituted methyl group; n1 to n3 may each independently be an integer from 1 to 20; and

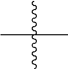

may be a position linked to Formula 1-1 or Formula 1-2.

In an embodiment, the quantum dot may include a core, and a shell surrounding the core; and the ligand and the protective layer may each be bonded on the surface of the shell.

In an embodiment, the core may include first semiconductor nanocrystals; the shell may include second semiconductor nanocrystals that are different from the first semiconductor nanocrystals; and the first semiconductor nanocrystals and the second semiconductor nanocrystals may each independently be a Group II-VI compound, a Group III-VI compound, a Group I-III-VI compound, a Group III-V compound, a Group III-II-V compound, a Group IV-VI compound, a Group IV element, a Group IV compound, or any combination thereof.

In an embodiment, the core may include InP or AgInGaS.

In an embodiment, the protective layer may surround the surface of the quantum dot.

In an embodiment, a method for preparing a quantum dot complex may include providing a first quantum dot complex including a quantum dot and a first ligand bonded on a surface of the quantum dot, exchanging the first ligand bonded to the first quantum dot complex with a second ligand including a hydrophilic group to form a second quantum dot complex, and reacting an aluminum oxide precursor with a surface of the second quantum dot complex.

In an embodiment, the aluminum oxide precursor may include at least one of trimethylaluminum, aluminum isopropoxide, and aluminum chloride.

In an embodiment, a protective layer which covers the second quantum dot complex may be formed by reacting the aluminum oxide precursor with the surface of the second quantum dot complex.

In an embodiment, the forming of the second quantum dot complex may include heating a first mixture including the first quantum dot complex, a first solvent, and the second ligand at a first temperature.

In an embodiment, the reacting of the aluminum oxide precursor with the surface of the second quantum dot complex may include putting a second mixture including the second quantum dot complex and a second solvent into a reactor and reacting the second mixture at a second temperature, and injecting the aluminum oxide precursor into the reactor.

In an embodiment, the reacting of the aluminum oxide precursor with the surface of the second quantum dot complex may further include injecting oxygen into the reactor after the injecting of the aluminum oxide precursor.

In an embodiment, the second ligand may be represented by Formula 1-1 or Formula 1-2.

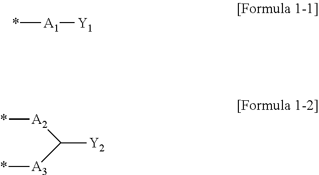

In Formula 1-1 and Formula 1-2, A₁ to A₃ may each independently be O, S, or NH; Y₁ and Y₂ may each independently be a moiety represented by one of Formula 2-1 to Formula 2-3; *---- and may be a position linked on the surface of the quantum dot.

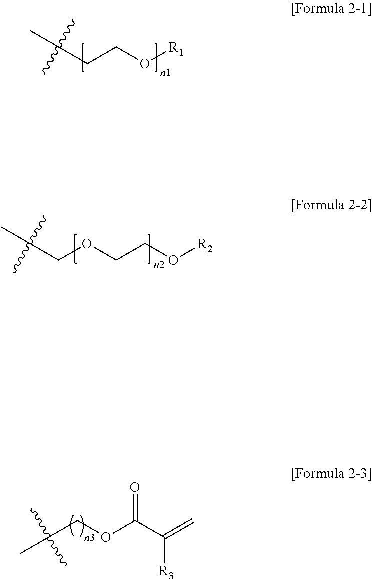

In Formula 2-1 to Formula 2-3, R₁ and R₂ may each independently be a substituted or unsubstituted oxy group, a substituted or unsubstituted thiol group, a substituted or unsubstituted alkyl group having 1 to 20 carbon atoms, or a substituted or unsubstituted alkenyl group having 2 to 20 carbon atoms; R₃ may be a hydrogen atom, or a substituted or unsubstituted methyl group; n1 to n3 may each independently be an integer from 1 to 20; and

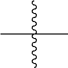

may be a position linked to Formula 1-1 or Formula 1-2.

In an embodiment, a maintenance rate of photoconversion efficiency of the quantum dot complex may be equal to or greater than about 90%, and the maintenance rate of photo conversion efficiency may be expressed by Equation 1.

$$Maintenance rate of photoconversion efficiency = ( {E}_{1} / {E}_{2} ) \times 100 \qquad [ Equation 1 ]$$

In Equation 1, E₁ may be a quantum yield measured after emitting, to the quantum dot, excitation light having a wavelength of about 460 nm with a light amount of about 60 mW/cm² for about 500 hours; and E₂ may be a quantum yield measured before emitting the excitation light.

In an embodiment, a display device may include a display panel, and a light conversion layer which is disposed on the display panel and includes light control parts, wherein

at least one of the light control parts may include a quantum dot complex; and the quantum dot complex may include a quantum dot, a ligand which is bonded on a surface of the quantum dot and includes a hydrophilic group, and a protective layer which is bonded on the surface of the quantum dot and includes an aluminum oxide.

In an embodiment, the display panel may include a light emitting element that generates first light; and the light conversion layer may include a first light control part that transmits the first light, a second light control part that converts the first light to second light, and a third light control part that converts the first light to third light.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of an electronic device according to an embodiment;

FIG. 2 is an exploded schematic perspective view of an electronic device according to an embodiment;

FIG. 3 is a schematic cross-sectional view of a portion of a display device according to an embodiment, and corresponding to line I-I′ of FIG. 2;

FIG. 4 is a schematic cross-sectional view of a light emitting element of an embodiment;

FIG. 5 is a schematic view of the structure of a quantum dot according to an embodiment;

FIG. 6 is an enlarged schematic plan view of a portion of a display device according to an embodiment;

FIG. 7 is a schematic cross-sectional view of the display device according to an embodiment;

FIG. 8 is a schematic cross-sectional view of a display device according to another embodiment;

FIG. 9 is a flowchart illustrating a method for preparing a quantum dot according to an embodiment;

FIG. 10 is a schematic view of one step of the method for preparing a quantum dot according to an embodiment; and

FIG. 11 is a graph showing the measurement of a maintenance rate of photoconversion efficiency over time of a photoconversion pattern according to Examples and Comparative Examples.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for case of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for case of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, “Group” refers to a Group in the IUPAC periodic table.

In the specification, “Group II” may include Group IIA elements and Group IIB elements. For example, the Group II elements may be magnesium (Mg) or zinc (Zn), but are not limited thereto.

In the specification, “Group III” may include Group IIIA elements and Group IIIB elements. For example, the Group III elements may be aluminum (Al), indium (In), gallium (Ga), or titanium (Ti), but are not limited thereto.

In the specification, “Group V” may include Group VA elements and Group VB elements. For example, the Group V elements may be phosphorus (P), arsenic (As), or antimony (Sb), but are not limited thereto.

In the specification, “Group VI” may include Group VIA elements and Group VIB elements. For example, the Group VI elements may be oxygen (O), sulfur (S), selenium (Se), or tellurium (Te), but are not limited thereto.

Hereinafter, a quantum dot according to an embodiment, a light emitting element, and a display device including the same will be described with reference to the accompanying drawings.

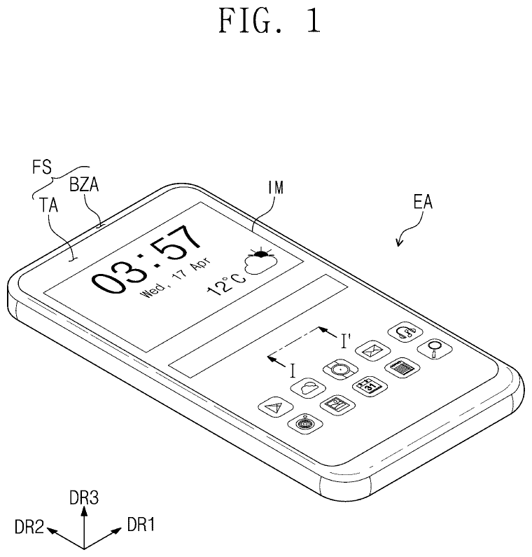

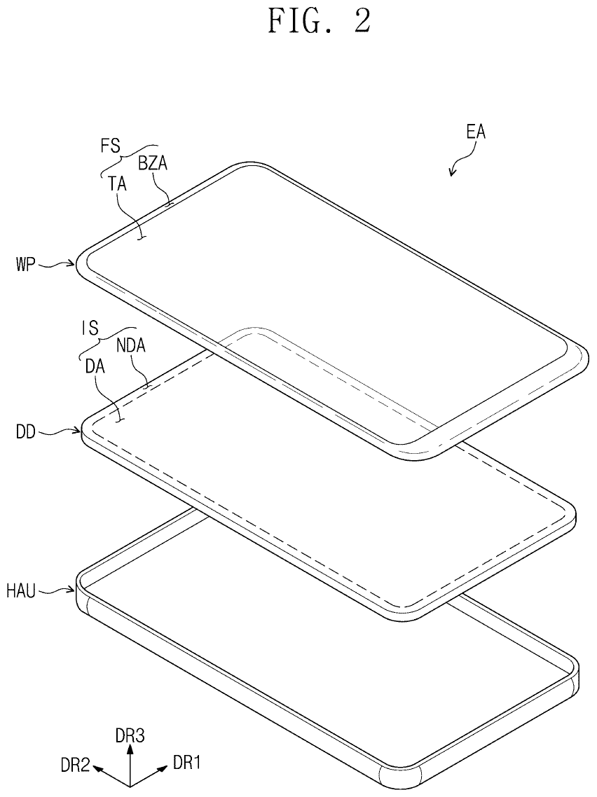

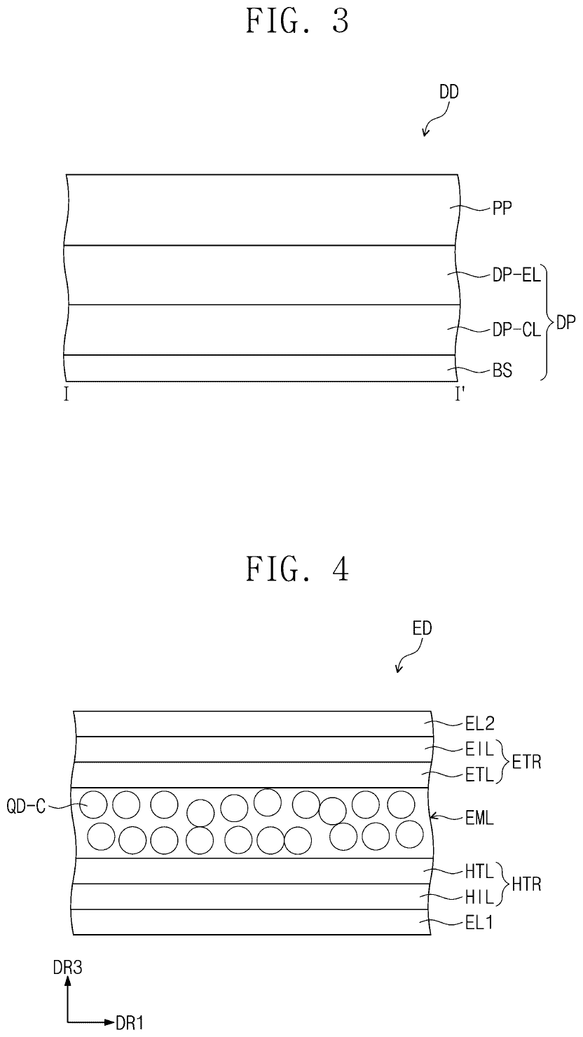

FIG. 1 is a schematic perspective view of an electronic device EA according to an embodiment. FIG. 2 is an exploded schematic perspective view of an electronic device EA according to an embodiment. FIG. 3 is a schematic cross-sectional view of a portion of a display device according to an embodiment, and corresponding to line I-I′ of FIG. 2. FIG. 4 is a schematic cross-sectional view of a light emitting element ED according to an embodiment.

In an embodiment, an electronic device EA may be a large-sized electronic device such as a television set, a monitor, or an outdoor billboard. The electronic device EA may be a small-sized and/or a medium-sized electronic device such as a personal computer, a laptop computer, a personal digital terminal, a car navigation unit, a game console, a smartphone, a tablet, or a camera. These devices are merely presented as examples, and thus it may be adopted for other electronic devices within the scope of the embodiments. In an embodiment, a smartphone is illustrated as the electronic device EA.

The electronic device EA may include a display device DD and a housing HAU. The display device DD may display an image IM through a display surface IS, and a user may view an image provided through a transmission region TA corresponding to a front surface FS of the electronic device EA. The image IM may include a still image as well as a dynamic image. FIG. 1 illustrates that the front surface FS is parallel to a plane defined by a first direction DR1 and a second direction DR2 crossing the first direction DR1. However, this is only an example, and in another embodiment, the front surface FS of the electronic device EA may have a curved shape.

Among the normal directions of the front surface FS of the electronic device EA, that is, the thickness directions of the electronic device EA, a direction in which the image IM is displayed may be indicated by a third direction DR3. A front surface (or an upper surface) and a rear surface (or a lower surface) of each member may be separated by the third direction DR3. The directions indicated by the first to third directions DR1, DR2 and DR3 may be a relative concept and thus may be converted to other directions.

Although not illustrated in the drawing, the electronic device EA may include a foldable display device having a folding region and a non-folding region, or a bending display device having at least one bent portion.

The electronic device EA may include a display device DD and a housing HAU. In the electronic device EA, the front surface FS may correspond to a front surface of the display device DD, and may correspond to a front surface of a window WP. Accordingly, the like reference character FS will be given for the front surface of the electronic device EA, the front surface of the display device DD, and the front surface of the window WP.

The housing HAU may receive the display device DD. The housing HAU may be disposed to cover the display device DD, such that a top surface, which is the display surface IS, of the display device DD is exposed. The housing HAU may cover the side surface and the bottom surface of the display device DD and may expose the entire top surface thereof. However, the embodiments are not limited thereto, and the housing HAU may cover a portion of the top surface of the display device DD as well as the side surface and the bottom surface thereof.

In the electronic device EA according to an embodiment, the window WP may include an optically transparent insulating material. The window WP may include a transmission region TA and a bezel region BZA. The front surface FS of the window WP including the transmission region TA and the bezel region BZA corresponds to the front surface FS of the electronic device EA.

In FIGS. 1 and 2, the transmission region TA is shown in a rectangular shape with vertices rounded. However, this is only an example, and the transmission region TA may have various shapes and is not limited to any one embodiment.

The transmission region TA may be an optically clear region. A bezel region BZA may have a light transmittance relatively lower than the transmission region TA. The bezel region BZA may have a certain color. The bezel region BZA may be adjacent to the transmission region TA, and may surround the transmission region TA. The bezel region BZA may define the shape of the transmission region TA. However, embodiments are not limited to the one illustrated, the bezel region BZA may be disposed adjacent to only one side of the transmission region TA, and a part thereof may be omitted.

The display device DD may be disposed under the window WP. In the description, “below” may also indicate a direction opposite to the direction in which the display device DD provides an image.

In an embodiment, the display device DD may be configured to generate an image IM. The image IM generated by the display device DD may be displayed on the display surface IS, and may be viewed by a user through the transmission region TA from the outside. The display device DD may include a display region DA and a non-display region NDA. The display region DA may be a region activated in response to an electrical signal. The non-display region NDA may be a region covered by the bezel region BZA. The non-display region NDA may be adjacent to the display region DA. The non-display region NDA may surround the display region DA.

Referring to FIG. 3, the display device DD may include a display panel DP and a light control layer PP disposed on the display panel DP. The display panel DP may include a display element layer DP-EL. The display element layer DP-EL may include a light emitting element ED.

The light control layer PP may be disposed on a display panel DP to control light that is reflected at the display panel DP from an external light. The light control layer PP may include, for example, a polarizing layer or a color filter layer.

The display panel DP of the display device in an embodiment may be a light emitting display panel. For example, the display panel DP may be a quantum dot light emitting display panel including a quantum dot light emitting element. However, embodiments are not limited thereto.

The display panel DP may include a base substrate BS, a circuit layer DP-CL disposed on the base substrate BS, and the display element layer DP-EL disposed on the circuit layer DP-CL.

The base substrate BS may provide a base surface on which the display element layer DP-EL is disposed. The base substrate BS may be a glass substrate, a metal substrate, a plastic substrate, or the like. However, embodiments are not limited thereto, and the base substrate BS may be an inorganic layer, an organic layer, or a composite material layer. The base substrate BS may be a flexible substrate which is readily bendable or foldable.

In an embodiment, the circuit layer DP-CL may be disposed on the base substrate BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting element ED of the element layer DP-EL.

FIG. 4 is a schematic cross-sectional view of a light emitting element ED according to an embodiment, and referring to FIG. 4, the light emitting element ED according to an embodiment may include a first electrode EL1, a second electrode EL2 facing the first electrode EL1, and functional layers disposed between the first electrode EL1 and the second electrode EL2 and which may include an emission layer EML.

The functional layers may further include a hole transport region HTR disposed between the first electrode EL1 and the emission layer EML, and an electron transport region ETR disposed between the emission layer EML and the second electrode EL2. Although not illustrated in the drawing, a capping layer may be further disposed on the second electrode EL2 in an embodiment.

The hole transport region HTR and the electron transport region ETR may each include sub functional layers. For example, the hole transport region HTR may include a hole injection layer HIL and a hole transport layer HTL as sub functional layers, and the electron transport region ETR may include an electron injection layer EIL and an electron transport layer ETL as sub functional layers. Embodiments are not limited thereto, and the hole transport region HTR may further include an electron blocking layer (not shown) as a functional sublayer, and the electron transport region ETR may further include a hole blocking layer (not shown) as a functional sublayer.

In the light emitting element ED according to an embodiment, the first electrode EL1 may have conductivity. The first electrode EL1 may be formed of a metal alloy or a conductive compound. The first electrode EL1 may be an anode. The first electrode EL1 may be a pixel electrode.

In the light emitting element ED according to an embodiment, the first electrode EL1 may be a reflective electrode. However, embodiments are not limited thereto. For example, the first electrode EL1 may be a transmissive electrode or a transflective electrode. If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). The first electrode EL1 may have a multilayer structure including a reflective layer or a transflective layer formed of the above-described material, and a transmissive conductive layer formed of indium tin oxide (ITO), indium zinc oxide (IZO), zinc oxide (ZnO), indium tin zinc oxide (ITZO) and the like. For example, the first electrode EL1 may be a multilayer metal film and have a structure in which a metal film of ITO/Ag/ITO is stacked.

The hole transport region HTR may be provided on the first electrode EL1. The hole transport region HTR may include a hole injection layer HIL, a hole transport layer HTL, etc. The hole transport region HTR may further include at least one of a hole buffer layer (not shown) or an electron blocking layer EBL in addition to the hole injection layer HIL and the hole transport layer HTL. The hole buffer layer (not shown) may compensate for a resonance distance according to the wavelength of light emitted from the emission layer EML, and may thus increase luminous efficiency. Materials which may be included in the hole transport region HTR may be used as materials included in the hole buffer layer (not shown). The electron blocking layer (not shown) may be a layer playing the role of preventing the electron injection from the electron transport region ETR to the hole transport region HTR.

The hole transport region HTR may be a layer consisting of a single material, a layer including different materials or a structure including multiple layers including different materials. For example, the hole transport region HTR may be a structure including different materials, or may be a structure in which a hole injection layer HIL/hole transport layer HTL, a hole injection layer HIL/hole transport layer HTL/hole buffer layer (not shown), a hole injection layer HIL/hole buffer layer (not shown), a hole transport layer HTL/hole buffer layer (not shown), or a hole injection layer HIL/hole transport layer HTL/electron blocking layer EBL (not shown) wherein the layers of each structure may be stacked in order from the first electrode EL1 in its respective stated order, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole injection layer HIL may include, for example, a phthalocyanine compound such as copper phthalocyanine; N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine] (m-MTDATA), 4,4′,4″-tris(N,N-diphenylamino)triphenylamine (TDATA), 4,4′,4″-tris{N,-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPD), triphenylamine-containing polyether ketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), etc.

The hole transport layer HTL may include general materials of the related art. The hole transport layer HTL may further include, for example, carbazole derivatives such as N-phenyl carbazole and polyvinyl carbazole, fluorene derivatives, N,N′-bis(3-methylphenyl)-N,N′-diphenyl-[1,1-biphenyl]-4,4′-diamine (TPD), triphenylamine derivatives such as 4,4′,4″-tris(N-carbazolyl)triphenylamine (TCTA), N,N′-di(naphthalene-1-yl)-N,N′-diphenyl-benzidine (NPD), 4,4′-cyclohexylidene bis[N,N-bis(4-methylphenyl|benzenamine] (TAPC), 4,4′-bis[N,N′-(3-tolyl)amino]3,3′-dimethylbiphenyl (HMTPD), 1,3-Bis(N-carbazolyl)benzene (mCP), etc.

The hole transport region HTR may have a thickness in a range of about 5 nm to about 1,500 nm. For example, the HTR may have a thickness in a range of about 10 nm to about 500 nm. The hole injection layer HIL may have a thickness of, for example, in a range of about 3 nm to about 100 nm, and the hole transport layer HTL may have a thickness in a range of about 3 nm to about 100 nm. For example, the electron blocking layer (not shown) may have a thickness in a range of about 1 nm to about 100 nm. If the thicknesses of the hole transport region HTR, the hole injection layer HIL, the hole transport layer HTL, and the electron blocking layer (not shown) satisfy the above-described ranges, satisfactory hole transport properties may be achieved without a substantial increase in driving voltage.

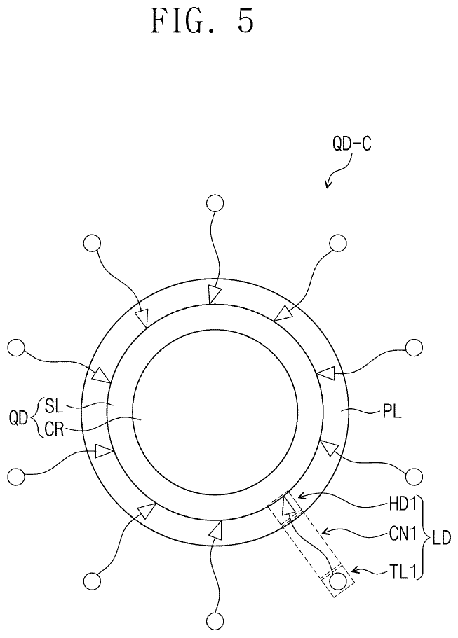

The emission layer EML may be provided on the hole transport region HTR. The emission layer EML may include a quantum dot complex QD-C. The quantum dot complex QD-C included in the emission layer EML may include a quantum dot QD (see FIG. 5), a ligand LD (see FIG. 5), and a protective layer PL (see FIG. 5). The quantum dot complex QD-C will be described later.

The emission layer EML may include quantum dot complexes QD-C. The quantum dot complexes QD-C included in the emission layer EML may be stacked to form a layer. In FIG. 4, for example, the quantum dot complexes QD-C having a circular cross-section may be arranged to form approximately two layers, but embodiments are not limited thereto. For example, the arrangement of the quantum dot complexes QD-C may vary according to a thickness of the emission layer EML, a shape of the quantum dot QD included in the emission layer EML, an average diameter of the quantum dot QD, a type of ligand LD bonded on a surface of the quantum dot QD, etc. For example, in the emission layer EML, the quantum dot complexes QD-C may be aligned to be adjacent to each other to form a single layer, or may be aligned to form multiple layers such as two or three layers.

A luminescence center wavelength of the emission layer EML may be in a range of about 500 nm to about 540 nm. The emission layer EML may emit green light having a wavelength in a range of about 500 nm to about 540 nm. However, embodiments are not limited thereto, and the emission layer EML may emit blue light or red light. The luminescence center wavelength of the emission layer EML may be in a range of about 430 nm to about 490 nm. The luminescence center wavelength of the emission layer EML may be in a range of about 590 nm to about 650 nm.

In the light emitting element ED according to an embodiment, an emission layer EML may include a host and a dopant. In an embodiment, the emission layer EML may include a quantum dot QD as a dopant material. In an embodiment, the emission layer EML may further include a host material.

In the light emitting element ED according to an embodiment, the emission layer EML may emit fluorescence. For example, a quantum dot QD may be used as a fluorescent dopant material.

In the light emitting element ED according to an embodiment, an electron transport region ETR may be provided on the emission layer EML. The electron transport region ETR may include at least one among a hole blocking layer (not shown), an electron transport layer ETL, and an electron injection layer EIL, but embodiments are not limited thereto.

The electron transport region ETR may be a layer consisting of a single material, a layer including different materials, or a structure including multiple layers formed of a plurality of different materials.

For example, the electron transport region ETR may have a single layer structure of the electron injection layer EIL or the electron transport layer ETL, and may have a structure including an electron injection material and an electron transport material. The electron transport region ETR may have a structure including different materials, or may have a structure in which an electron transport layer ETL/electron injection layer EIL, a hole blocking layer (not shown)/electron transport layer ETL/electron injection layer EIL are stacked in order from the emission layer EML in this stated order, but embodiments are not limited thereto. The thickness of the electron transport region ETR may be, for example, in a range of about 20 nm to about 150 nm.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

When the electron transport region ETR includes the electron transport layer ETL, the electron transport region ETR may include an anthracene-based compound. However, embodiments are not limited thereto, and the electron transport region may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), or a mixture thereof. A thickness of the electron transport layer ETL may be in a range of about 10 nm to about 100 nm. For example, the thickness of the electron transport layer ETL may be in a range of about 15 nm to about 50 nm. If the thickness of the electron transport layer ETL satisfies the above-described ranges, satisfactory electron transport properties may be obtained without substantial increase of a driving voltage.

If the electron transport region ETR includes the electron injection layer EIL, the electron transport region ETR may include a metal halide such as LiF, NaCl, CsF, RbCl, and RbI; a lanthanide metal such as Yb; a metal oxide such as Li₂O and BaO; or lithium quinolate (LiQ), etc., but embodiments are not limited thereto. The electron injection layer EIL may include a mixture of an electron transport material and an insulating organometallic salt. For example, the organometallic salt may include a metal acetate, a metal benzoate, a metal acetoacetate, a metal acetylacetonate, or a metal stearate. A thickness of the electron injection layer EIL may be in a range of about 0.1 nm to about 10 nm. For example, a thickness of the electron injection layer EIL may be in a range of about 0.3 nm to about 9 nm. If the thickness of the electron injection layer EIL satisfies the above described range, satisfactory electron injection properties may be obtained without inducing substantial increase of a driving voltage.

The electron transport region ETR may include a hole blocking layer (not shown) as described above. The hole blocking layer (not shown) may include, for example, at least one of 2,9-dimethyl-4,7-diphenyl-1,10-phenanthroline (BCP) or 4,7-diphenyl-1,10-phenanthroline (Bphen), but is not limited thereto.

The second electrode EL2 may be provided on the electron transport region ETR. The second electrode EL2 may be a common electrode or a cathode. The second electrode EL2 may be a transmissive electrode, a transflective electrode or a reflective electrode. If the second electrode EL2 is the transmissive electrode, the second electrode EL2 may include a transparent metal oxide, for example, indium tin oxide (ITO), indium zinc oxide (IZO) zinc oxide (ZnO), indium tin zinc oxide (ITZO), etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, a compound thereof (for example, AgYb, a compound of AgMg and MgAg depending on the content thereof), or a mixture thereof (for example, a mixture of Ag and Mg). The second electrode EL2 may have a multilayer structure including a reflective layer or a transflective layer formed of the above-described materials and a transparent conductive layer formed of indium tin oxide (ITO), indium zinc oxide (IZO) zinc oxide (ZnO), indium tin zinc oxide (ITZO), etc.

Although not shown, the second electrode EL2 may be electrically connected with an auxiliary electrode. If the second electrode EL2 is electrically connected with the auxiliary electrode, the resistance of the second electrode EL2 may decrease.

FIG. 5 is a schematic view of the structure of the quantum dot complex according to an embodiment.

Referring to FIG. 5, the quantum dot complex QD-C may include a quantum dot QD, a protective layer PL, and a ligand LD. The quantum dot QD may include a core CR, and a shell SL surrounding the core CR. The shell SL may entirely surround the core CR.

The quantum dot QD may include semiconductor nanocrystals which may be selected from a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSc, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂, CuGaO₂, AgGaO₂, AgAlO₂, and a mixture thereof; or a quaternary compound such as AgInGaS₂ or CuInGaS₂, or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof, or any combination thereof. In an embodiment, a Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof, or any combination thereof. Examples of a Group IV element may include Si, Ge, or any mixture thereof. The Group IV compound may include a binary compound selected from the group consisting of SiC, SiGe, and any mixture thereof.

A binary compound, a ternary compound, or a quaternary compound may be present in a particle at a uniform concentration distribution, or may be present in a same particle at a partially different concentration distribution. In an embodiment, the quantum dot may have a core/shell structure in which one quantum dot surrounds another quantum dot. A quantum dot having a core/shell structure may have a concentration gradient in which the concentration of a material present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or a may serve as a charging layer to impart electrophoresis properties to the quantum dot. The shell may be a single layer or a multilayer.

The shell SL may include materials different from the core CR. For example, the core CR may include first semiconductor nanocrystals and the shell SL may include second semiconductor nanocrystals that are different from the first semiconductor nanocrystals. The shell SL may include a metal oxide or a non-metal oxide. The shell SL may include a metal oxide or a non-metal oxide, semiconductor nanocrystals, or any combination thereof.

The shell SL may be formed of a single material, but may be formed to have a concentration gradient. For example, the shell SL may have a concentration gradient in which the concentration of the second semiconductor nanocrystals present in the shell SL decreases toward the core and the concentration of the first semiconductor nanocrystals included in the core CR increases toward the center of the core CR.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; or a ternary compound such as MgAl₂O₄, CoFe₂O₄, NiFe₂O₄, or CoMn₂O₄, but embodiments are not limited thereto.

Examples of a semiconductor compound may include CdS, CdSe, CdTe, ZnS, ZnSc, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width of half maximum (FWHM) of a light emitting wavelength spectrum of equal to or less than about 45 nm., For example, the quantum dot may have a FWHM of a light emitting wavelength spectrum of equal to or less than about 40 nm. For example, the quantum dot may have a FWHM of a light emitting wavelength spectrum of equal to or less than about 30 nm. Color purity or color reproducibility may be improved in any of the above ranges. Light emitted through a quantum dot may be emitted in all directions, and thus a wide viewing angle may be improved.

Although the form of the quantum dot is not limited to forms of the related art, the quantum dot may have a spherical shape, a pyramidal shape, a multi-arm shape, or the quantum dot may be in the form of cubic nanoparticles, nanotubes, nanowires, nanofibers, nanoplate particles, etc.

A quantum dot QD may control the color of emitted light according to the particle size thereof, and thus the quantum dot QD may have various light emission colors such as blue, red, green, etc. The smaller the particle size of the quantum dot QD becomes, light in a shorter wavelength region may be emitted. For example, in the quantum dot QD having the same core, the particle size of a quantum dot emitting green light may be smaller than the particle size of a quantum dot emitting red light. In the quantum dot QD having the same core, the particle size of a quantum dot emitting blue light may be smaller than the particle size of a quantum dot emitting green light. However, embodiments are not limited thereto, and even in the quantum dot QD having the same core, the particle size may be adjusted according to forming-materials and thickness of a shell.

When a quantum dot QD has various light emission colors such as blue, red, green, etc., the quantum dot QD having a different light emission color may have a different core material.

In an embodiment, the core CR may contain a Group III-V compound or a Group I-III-VI compound. For example, the core CR may include InP or AgInGaS. The quantum dot QD according to an embodiment includes the core CR containing a Group III-V compound or a Group I-III-VI compound, and thus may have a high blue light absorption rate.

In an embodiment, the quantum dot QD may be a non-Cd-based quantum dot. For example, the quantum dot QD may not include cadmium (Cd).

The absorption wavelength of the core CR may be in a range of about 350 nm to about 530 nm. Accordingly, the core CR may absorb blue light in the above-described wavelength range to emit green light or red light. The emission wavelength of the light emitted from the quantum dot QD may be adjusted by adjusting the size of the core CR, the thickness of the shell SL, or the like.

In an embodiment, the quantum dot QD may emit light having an emission wavelength in a range of about 510 nm to about 540 nm. For example, the quantum dot QD may emit green light having an emission wavelength in a range of about 510 nm to about 540 nm. However, embodiments are not limited thereto, the quantum dot QD may emit light having an emission wavelength of about 630 nm to about 680 nm. For example, the quantum dot QD may emit red light having an emission wavelength in a range of about 630 nm to about 680 nm. The quantum dot QD may emit light having a desired emission wavelength by adjusting the content of elements contained in the core CR.

In an embodiment, the diameter of the quantum dot QD may be in a range of about 1 nm to about 10 nm. When the quantum dot QD satisfies the average particle diameter range as described above, the quantum dot QD may not only exhibit behavior characteristics of the quantum dot QD, but also have excellent dispersibility. Moreover, the emission wavelength of the quantum dot QD and/or semiconductor characteristics of the quantum dot, and the like may be variously modified by variously selecting the average particle diameter of the quantum dot QD in the aforementioned range.

The quantum dot complex QD-C may include the ligand LD bonded on the surface of the quantum dot QD. The ligand LD bonded to the quantum dot QD may contain a hydrophilic group. The quantum dot complex QD-C may have modified surface characteristics by the attachment of the ligand LD containing the hydrophilic group to the surface of the quantum dot QD.

The quantum dot QD contained in the quantum dot complex QD-C may include a core CR and a shell SL surrounding the core CR. The ligand LD may be bonded on the surface of the shell SL which constitutes the surface of the quantum dot QD.

In an embodiment, the ligand LD may include at least one of an ethylene glycol group or a (meth)acrylate group. For example, the ligand LD may include any one among an ethylene glycol group or a (meth)acrylate group. The ethylene glycol group and the (meth)acrylate group are hydrophilic groups, and may play a role in increasing the dispersibility when the quantum dot complexes QD-C are dispersed in a solvent. In an embodiment, the ligand LD may include at least one of a polyethylene glycol group or a (meth)acrylate group. For example, the ligand LD may include one of a polyethylene glycol group and a (meth)acrylate group.

In an embodiment, the ligand LD may include a first head part HD1 bonded to the quantum dot QD, a first linking part CN1 which is linked to the first head part HD1, and a first tail part TL1 linked to the first linking part CN1. The first head part HD1 may be bonded on the surface of the quantum dot QD. The first head part HD1 may be bonded on the surface of the shell SL. When the first head part HD1 includes a single functional group in order to be bonded on the surface of the quantum dot QD, the ligand LD may be a monodentate ligand. When the first head part HD1 includes two functional groups in order to be bonded on the surface of the quantum dot QD, the ligand LD may be a bidentate ligand. The first head part HD1 may include a functional group for being bonded on the surface of the shell SL of the quantum dot QD, and thus the ligand LD may be effectively bonded to the quantum dot QD.

The first head part HD1 may be an electron donating head part. The first head part HD1 may have a structure containing anions in the functional group. In an embodiment, the first head part HD1 may be one of a thiol group, a dithioic acid group, a phosphine group, a catechol group, an amine group, or a carboxylic acid group.

The ligand LD may include the first tail part TL1. The first tail part TL1 may be linked to the first head part HD1. In an embodiment, the first head part HD1 may be bonded on the surface of the quantum dot QD, and the first tail part TL1 may be exposed to the outside of the quantum dot QD. In an embodiment, the first tail part TL1 may include a substituted or unsubstituted oxy group, a substituted or unsubstituted thiol group, a substituted or unsubstituted (meth)acrylate group, a substituted or unsubstituted alkyl group having 1 to 30 carbon atoms, or a substituted or unsubstituted alkenyl group having 2 to 30 carbon atoms. For example, the first tail part TL1 may be a substituted or unsubstituted methyl group, a substituted or unsubstituted methoxy group, or a substituted or unsubstituted acrylate group.

The ligand LD may include the first linking part CN1. The first linking part CN1 of the ligand LD may be linked to the first head part HD1. The first linking part CN1 may link the first head part HD1 and the first tail part TL1. For example, the ligand LD may include the first head part HD1, the first linking part CN1, and the first tail part TL1, the first linking part CN1 may be linked to the first head part HD1, and the first tail part TL1 may be linked to the first linking part CN1. However, embodiments are not limited thereto, and the first tail part TL1 may be omitted in the ligand LD.

In an embodiment, the ligand LD may contain an ethylene glycol group. The first linking part CN1 of the ligand LD may contain an ethylene glycol group. The first linking part CN1 may contain the ethylene glycol group represented by Formula E. The first linking part CN1 may be represented by Formula E:

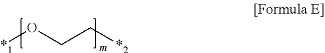

In Formula E, one of “*₁” and “*₂” may be a position linked to the first head part HD1, and the other may be a position linked to the first tail part TL1. For example, “*₁” may be linked to the first head part HD1, and “*₂” may be linked to the first tail part TL1. In an embodiment, “*₁” may be linked to the first tail part TL1, and “*₂” may be linked in the first head part HD1.

In Formula E, m may be from 1 to 20.

In an embodiment, the ligand LD may contain a polyethylene glycol group. The first linking part CN1 of the ligand LD may contain a polyethylene glycol group. For example, in Formula E, m may be an integer from 2 or greater.

The ligands LD may be bonded to cations provided to the surface of the shell SL of the quantum dot QD. In an embodiment, the shell SL may include a semiconductor compound selected from among a Group II-VI compound, a Group III-VI compound, a Group I-III-VI compound, a Group III-V compound, a Group III-II-V compound, a Group IV-VI compound, a Group IV element, a Group IV compound, and a combination thereof, and the cations of group I, group II, group III, and/or group IV elements included in the shell SL may be bonded to the ligands LD. For example, the shell SL may contain ZnSeS, and the ligands LD may be bonded to Zn cations contained in the shell SL. For example, the first head part HD1 of the ligand LD may be bonded to Zn cations provided on the surface of the shell SL. However, embodiments are not limited thereto.

In the specification, the term “substituted or unsubstituted” may describe a group that is unsubstituted or substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may be itself substituted or unsubstituted. For example, a biphenyl group may be interpreted as an aryl group or it may be interpreted as a phenyl group substituted with a phenyl group.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group including at least one carbon-carbon double bond in the middle or at a terminus of an alkyl group having at least two carbon atoms. An alkenyl group may be linear or branched. The number of carbon atoms in an alkenyl group is not limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, the number of carbon atoms in an amine group is not limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, the (meth)acrylate may be acrylate or methacrylate.

In the specification, the symbols “ [symbol] ” and “ [symbol] ” each represent a bonding site to a neighboring atom.

In the quantum dot complex QD-C according to an embodiment, the ligand may be represented by Formula 1-1 or Formula 1-2:

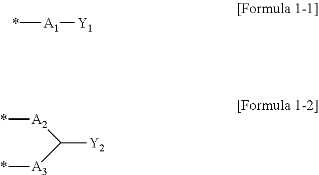

In Formula 1-1 and Formula 1-2, A₁ to A₃ may each independently be O, S, or NH. For example, A₁ to A₃ may each independently be O or S. For example, A₂ may be the same as A₃.

In Formula 1-1 and Formula 1-2, *---- is a position linked to the surface of the quantum dot.

In Formula 1-1 and Formula 1-2, Y₁ and Y₂ may each independently be a moiety represented by one of Formula 2-1 to Formula 2-3:

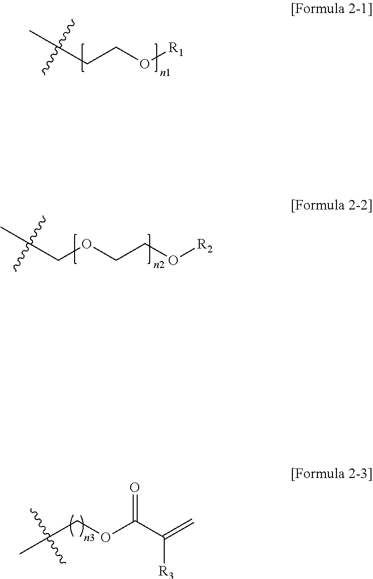

In Formula 2-1 and Formula 2-2, R₁ and R₂ may each independently be a substituted or unsubstituted oxy group, a substituted or unsubstituted thiol group, a substituted or unsubstituted alkyl group having 1 to 20 carbon atoms, or a substituted or unsubstituted alkenyl group having 2 to 20 carbon atoms. For example, R₁ and R₂ may each independently be a substituted or unsubstituted methyl group or a substituted or unsubstituted methoxy group.

In Formula 2-3, R₃ may be a hydrogen atom or a substituted or unsubstituted methyl group. For example, R₃ may be a hydrogen atom.

In Formula 2-1 and Formula 2-3, n1 to n3 may each independently be an integer from 1 to 20. In an embodiment, n1 to n3 may each independently be an integer from 2 to 20.

In Formula 2-1 to Formula 2-3,

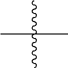

may be a position linked to Formula 1-1 or Formula 1-2.

In an embodiment, a moiety represented by Formula 2-3 may be represented by Formula 2-3-1:

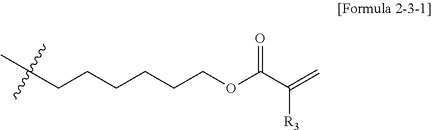

Formula 2-3-1 represents a case where the number of n3 is further defined in Formula 2-3. In Formula 2-3-1, R₃ is the same as described in Formula 2-3.

In an embodiment, the protective layer PL may be disposed on the surface of the quantum dot QD. The protective layer PL may prevent the migration, detachment, etc. of the ligands LD disposed on the surface of the quantum dot QD. The protective layer PL may serve to fix the ligands LD on the surface of the quantum dot QD. The quantum dot complex QD-C according to an embodiment may have excellent passivation effects to the quantum dot QD since the ligands LD are fixed on the quantum dot QD by the protective layer PL. Accordingly, the quantum dot complex QD-C according to an embodiment may exhibit high quantum yield characteristics.

The protective layer PL may surround the quantum dot QD. The protective layer PL may surround the shell SL which constitutes the surface of the quantum dot QD. In an embodiment, the protective layer PL may include an aluminum oxide. The protective layer PL may be formed of an aluminum oxide. The aluminum oxide included in the protective layer PL may be bonded on the surface of the quantum dot QD. The aluminum oxide included in the protective layer PL may be bonded on the surface of the shell SL. For example, the Al atom of the aluminum oxide may be bonded on the surface of the shell SL. In an embodiment, the Al element of the aluminum oxide may be a bonded anion provided on the surface of the shell SL, but embodiments are not limited thereto.

In an embodiment, the ligand LD may be bonded to an aluminum oxide. The ligand LD may be bonded on the surface of the quantum dot QD, and may be bonded to the aluminum oxide included in the protective layer PL. When the ligand LD is bonded to the aluminum oxide, the ligand may be represented by Formula 3-1 or Formula 3-2. However, the structure of the ligand is not limited thereto.

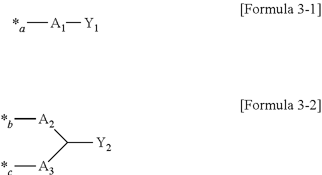

In Formula 3-1, “*ₐ” may be bonded to the aluminum oxide. For example, “*ₐ” may be bonded to the Al element of the aluminum oxide.

In Formula 3-2, at least one of “*_{b}” or “*_{c}” may be bonded to the aluminum oxide. Any one of “*_{b}” and “*_{c}” may be bonded on the surface of the quantum dot QD, and the other may be bonded to the aluminum oxide. For example, “*_{b}” may be bonded to the cation provided on the surface of the shell SL, and “*_{c}” may be bonded to the A₁ element of the aluminum oxide.

In Formula 3-1 and Formula 3-2, A₁ to A₃, Y₁, and Y₂ are the same as defined in Formula 1-1 and Formula 1-2.

The quantum dot complex QD-C according to an embodiment includes the ligand containing a hydrophilic group and the protective layer PL bonded to the quantum dot QD, and thus both quantum yield and crystal stability may be improved. The surface of the quantum dot QD and the ligand LD form a dynamic bond, and accordingly, the ligand may gradually move or be removed during the quantum dot purification and the preparation of the ink pattern. In embodiments, a bonding strength between the ligand LD and the quantum dot QD may be improved by introducing the protective layer PL. Accordingly, the quantum dot complex QD-C according to an embodiment may have excellent passivation effects, and may maintain high photoluminescence quantum yield and crystal stability.

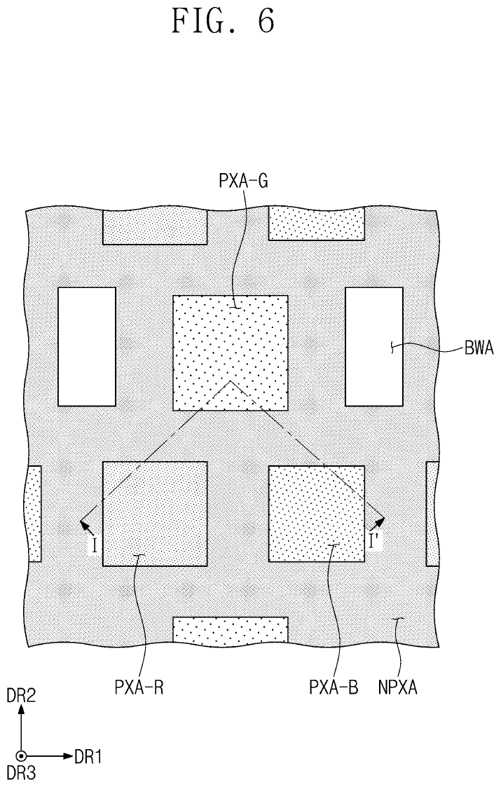

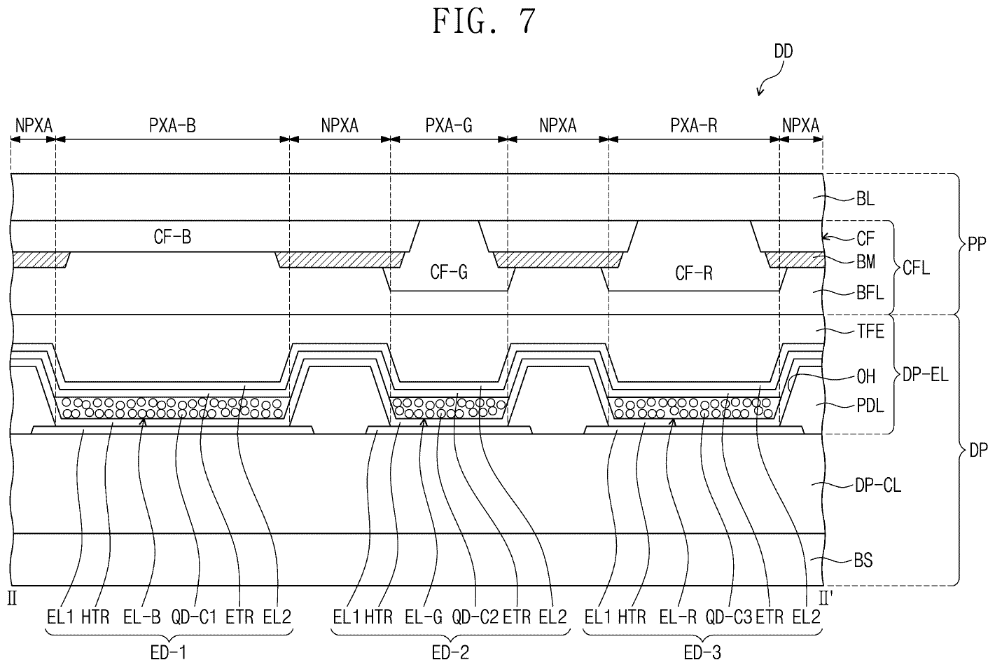

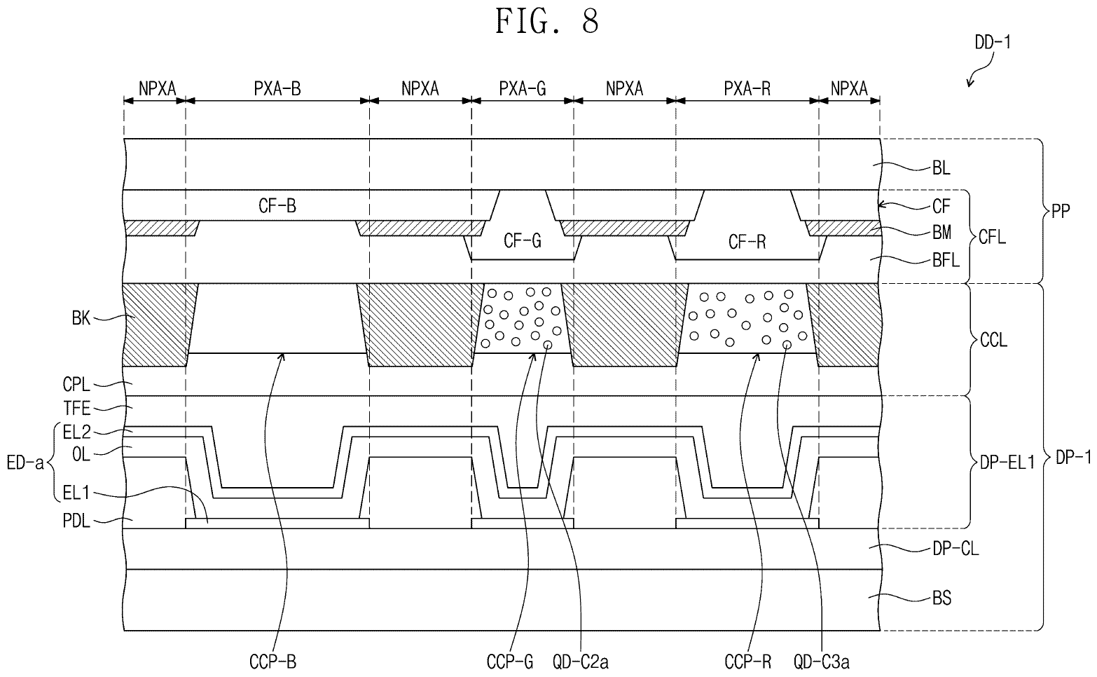

FIG. 6 is an enlarged schematic plan view of a portion of a display device DD according to an embodiment. FIG. 7 is a schematic cross-sectional view of the display device DD according to an embodiment. FIG. 7 illustrates a part taken along line II-II′ of FIG. 6. FIG. 8 is a cross-sectional view of a display device DD-1 according to another embodiment.

Referring to FIGS. 6 to 8, the display devices DD and DD-1 may include non-light emitting regions NPXA and light emitting regions PXA-B, PXA-G, and PXA-R. Each of the light emitting regions PXA-B, PXA-G and PXA-R may be a region which emits light generated from each of the light emitting elements ED-1, ED-2, and ED-3. The light emitting regions PXA-B, PXA-G, and PXA-R may be spaced apart from each other in a plan view.

The light emitting regions PXA-B, PXA-G and PXA-R may be divided into groups according to the color of light generated from the light emitting elements ED-1, ED-2, and ED-3. In the display devices DD and DD-1 according to them embodiments illustrated in FIGS. 6 to 8, three light emitting regions PXA-B, PXA-G, and PXA-R which emit blue light, green light, and red light respectively are illustrated. For example, the display devices DD and DD-1 according to embodiments may include a first light emitting region PXA-B, a second light emitting region PXA-G, and a third light emitting region PXA-R. In the specification, the first light emitting region PXA-B may be referred to as a blue light emitting region, the second light emitting region PXA-G may be referred to as a green light emitting region, and the third light emitting region PXA-R may be referred to as a red light emitting region.

FIG. 6 illustrates that the first to third light emitting regions PXA-B, PXA-G, and PXA-R have the same shape on a plane, and different areas on a plane, but embodiments are not limited thereto. At least two of the first to third light emitting regions PXA-B, PXA-G, and PXA-R may have a same area. The areas of the first to third light emitting regions PXA-B, PXA-G, and PXA-R may be set according to light emitting color. Among primary colors, an area of the pixel region which emits red light may be the largest, and an area of the pixel region which emits blue light may be the smallest.

FIG. 6 illustrates that the first to third light emitting regions PXA-B, PXA-G, and PXA-R may each have a rectangular shape in a plan view, but embodiments are not limited thereto. In a plan view, the first to third light emitting regions PXA-B, PXA-G, and PXA-R may each have different shapes such as a diamond shape or a pentagon shape. For example, the first to third light emitting regions PXA-B, PXA-G, and PXA-R may each have a rectangular shape with rounded corners.

FIG. 6 illustrates that the second light emitting region PXA-G is disposed in a first row, and the first light emitting region PXA-B and the third light emitting region PXA-R are disposed in a second row. However, this is only an example, and the disposition of the first to third light emitting regions PXA-B, PXA-G, and PXA-R may be arranged in different configurations. For example, the first to third light emitting regions PXA-B, PXA-G, and PXA-R may be disposed in a same row.

Any one among the first to third light emitting regions PXA-B, PXA-G, and PXA-R may emit a first color light, another may emit a second color light different from the first color light, and the other may emit a third color light different from the first color light and the second color light. In the specification, the first light emitting region PXA-B provides first light corresponding to some of the source light. For example, the third light emitting region PXA-R may emit red light, the second light emitting region PXA-G may emit green light, and the third light emitting region PXA-B may emit blue light.

A bank well region BWA may be defined in the display region DA (see FIG. 2). The bank well region BWA may be a region for preventing defects caused by erroneous jetting during a process of patterning a plurality of light control parts CCP1, CCP2, and CCP3 included in a light conversion layer CCL (see FIG. 8) which will be described later. The bank well region BWA may be a region in which a portion of banks BK (see FIG. 8) is removed. FIG. 6 illustrates that two bank well regions BWA are formed to be adjacent to the second light emitting region PXA-G, but embodiments are not limited thereto, and the shape and disposition of the bank well regions BWA may be changed variously.

Referring to FIG. 7, the light emitting elements ED-1, ED-2, and ED-3 may emit light beams having wavelengths different from each other. For example, in an embodiment, the display device DD may include a first light emitting element ED-1 which emits blue light, a second light emitting element ED-2 which emits green light, and a third light emitting element ED-3 which emits red light. However, the embodiment is not limited thereto, and the first to the third light emitting elements ED-1, ED-2, and ED-3 may emit light beams in the same wavelength range or at least one light emitting element emits light having a wavelength different from those of the others.

For example, the blue light emitting region PXA-B, the green light emitting region PXA-G, and the red light emitting region PXA-R of the display device DD may correspond to the first light emitting element ED-1, the second light emitting element ED-2, and the third light emitting element ED-3, respectively.

The display device DD may include light emitting elements ED-1, ED-2, and ED-3, and at least one among the light emitting elements ED-1, ED-2, and ED-3 may include emission layers EL-B, EL-G, and EL-R including quantum dots QD-C1, QD-C2, and QD-C2 according to an embodiment.

The display device DD according to an embodiment may include a display panel DP containing the light emitting elements ED-1, ED-2 and ED-3, and a light control layer PP disposed on the display panel DP. Although not illustrated in the drawing, the light control layer PP may be omitted from the display device DD according to an embodiment.

The display panel DP may include a base substrate BS, a circuit layer DP-CL, and a display element layer DP-EL provided on the base substrate BS, and the display element layer DP-EL may include a pixel defining film PDL, light emitting elements ED-1, ED-2 and ED-3 disposed between the pixel defining film PDL, and an encapsulation layer TFE disposed on the light emitting elements ED-1, ED-2 and ED-3.

A first emission layer EL-B of a first light-emitting device ED-1 may include a first quantum dot QD-C1. The first quantum dot QD-C1 may emit blue light that is first light.

A second emission layer EL-G of a second light-emitting device ED-2 and a third emission layer EL-R of a third light-emitting device ED-3 may include a second quantum dot QD-C2 and a third quantum dot QD-C3, respectively. The second quantum dot QD-C2 and the third quantum dot QD-C3 may emit green light that is second light, and red light that is third light, respectively.

At least one among the first to third quantum dots QD-C1, QD-C2, and QD-C2 may be the quantum dot according to the embodiment as described above. In an embodiment, the second quantum dot QD-C2 may be the quantum dot according to the embodiment as described above. However, embodiments are not limited thereto, and the first to third quantum dots QD-C1, QD-C2, and QD-C2 may each be the quantum dot according to the embodiment as described above.

In an embodiment, the first to third quantum dots QD-C1, QD-C2, and QD-C2 included in the light emitting elements ED-1, ED-2, and ED-3 may be formed of different core materials. The first to third quantum dots QD-C1, QD-C2, and QD-C2 may be formed of the same core material, or two quantum dots selected from among the first to third quantum dots QD-C1, QD-C2, and QD-C2 may be formed of the same core material, and the other may be formed of a different core material.

In an embodiment, the first to third quantum dots QD-C1, QD-C2, and QD-C2 may have different diameters. For example, the first quantum dot QD-C1 used in the first light emitting element ED-1 emitting light in a relatively short wavelength range may have a relatively smaller average diameter than the second quantum dot QD-C2 of the second light emitting element ED-2 and the third quantum dot QD-C2 of the third light emitting element ED-3 each emitting light in a relatively long wavelength region.

In the description, the average diameter refers to the arithmetic mean of the diameters of multiple quantum dot particles. The diameter of the quantum dot particle may be the average value of the width of the quantum dot particle in a cross section.

The relationship of the average diameters of the first to third quantum dots QD-C1, QD-C2 and QD-C2 is not limited to the above limitations. For example, FIG. 7 illustrates that the first to third quantum dots QD-C1, QD-C2, and QD-C2 are similar in size to one another. Although different from the one illustrated, the first to third quantum dots QD-C1, QD-C2, and QD-C2 included in the light emitting elements ED-1, ED-2, and ED-3 may be different in size. The average diameter of two quantum dots selected from the first to third quantum dots QD-C1, QD-C2, and QD-C2 may be similar, and the remainder may be different.

In the display device DD according to an embodiment, as shown in FIGS. 6 and 7, the areas of the light emitting regions PXA-B, PXA-G and PXA-R may each be different from one another. The areas may be areas in a plan view defined by the first direction DR1 and the second direction DR2.

The light emitting regions PXA-B, PXA-G and PXA-R may have different areas according to the color emitted from the emission layers EL-B, EL-G, and EL-R of the light emitting elements ED-1, ED-2, and ED-3. For example, with reference to FIGS. 6 and 7, in the display device DD according to an embodiment, the blue light emitting region PXA-B corresponding to the first light emitting element ED-1, which emits blue light, may have the largest area, and the green light emitting region PXA-G corresponding to the second light emitting element ED-2, which emits green light, may have the smallest area. However, the embodiment is not limited thereto. Thus, the light emitting regions PXA-B, PXA-G, and PXA-R may emit light having colors different from blue, green, and red colors, the light emitting regions PXA-B, PXA-G, and PXA-R may have the same area, or the light emitting regions PXA-B, PXA-G, and PXA-R may be provided at a different area ratio than that illustrated in FIG. 6.

Each of the light emitting regions PXA-R, PXA-G, and PXA-B may be a region separated by the pixel defining film PDL. The non-light emitting regions NPXA may be regions between the adjacent light emitting regions PXA-B, PXA-G, and PXA-R, which correspond to the pixel defining film PDL. In the specification, the light emitting regions PXA-B, PXA-G, and PXA-R may each correspond to a pixel. The pixel defining film PDL may divide the light emitting elements ED-1, ED-2, and ED-3. The emission layers EL-B, EL-G and EL-R of the light emitting elements ED-1, ED-2 and ED-3 may be disposed and separated in an opening OH defined by the pixel defining film PDL.

The pixel defining film PDL may be formed of a polymer resin. For example, the pixel defining film PDL may include a polyacrylate-based resin or a polyimide-based resin. The pixel defining film PDL may further include an inorganic material in addition to the polymer resin. The pixel defining film PDL may include a light absorbing material or a black pigment or a black dye. The pixel defining film PDL including a black pigment or a black dye may form a black pixel definition layer. Carbon black or the like may be used as the black pigment or black dye in formation of the pixel defining film PDL, but the embodiment is not limited thereto.

The pixel defining film PDL may be formed of an inorganic material. For example, the pixel defining film PDL may include silicon nitride (SiNx), silicon oxide (SiOx), silicon oxynitride (SiOxNy), etc. The pixel defining film PDL may define the light emitting regions PXA-B, PXA-G, and PXA-R. The light emitting regions PXA-B, PXA-G, and PXA-R and the non-light emitting regions NPXA may be separated by the pixel defining films PDL.

The light emitting elements ED-1, ED-2 and ED-3 may each include a first electrode EL1, a hole transport region HTR, emission layers EL-B, EL-G and EL-R, an electron transport region ETR, and a second electrode EL2. The description in FIG. 4 may be equally applied to the first electrode EL1, the hole transport region HTR, the electron transport region ETR, and the second electrode EL2, except that the first to third quantum dots QD-C1, QD-C2, and QD-C2 included in the emission layers EL-B, EL-G, and EL-R may be different from one another in the light emitting elements ED-1, ED-2, and ED-3 included in the display device DD according to an embodiment. Although not illustrated, each of the light emitting elements ED-1, ED-2, and ED-3 may further include a capping layer between the second electrode EL2 and the encapsulation layer TFE.

The encapsulation layer TFE may cover the light emitting elements ED-1, ED-2, and ED-3. The encapsulation layer TFE may be formed by laminating one layer or a plurality of layers. The encapsulation layer TFE may be a thin film encapsulation layer. The encapsulation layer TFE may protect the light emitting elements ED-1, ED-2, and ED-3. The encapsulation layer TFE may cover an upper surface of the second electrode EL2 disposed in the opening OH, and may fill the opening OH.

In FIG. 7, the hole transport region HTR and the electron transport region ETR are illustrated to be provided as a common layer while covering the pixel defining film PDL, but embodiments are not limited thereto. In an embodiment, the hole transport region HTR and the electron transport region ETR may be disposed in the opening OH defined by the pixel defining film PDL.

For example, when the hole transport region HTR and the electron transport region ETR in addition to the emission layers EL-B, EL-G, and EL-R are provided through an inkjet printing method, the hole transport region HTR, the emission layers EL-B, EL-G, and EL-R, the electron transport region ETR, etc. may be provided corresponding to the defined opening OH between the pixel defining film PDL. However, the embodiment is not limited thereto, and as shown in FIG. 7, the hole transport region HTR and the electron transport region ETR may cover the pixel defining film PDL without being patterned, and may be provided as one common layer regardless of a method of providing each functional layer.

In the display device DD according to an embodiment illustrated in FIG. 7, although the thicknesses of the emission layers EL-B, EL-G, and EL-R of the first to third light emitting elements ED-1, ED-2, and ED-3 are illustrated to be similar to one another, the embodiment is not limited thereto. For example, in an embodiment, the thicknesses of the emission layers EL-B, EL-G, and EL-R of the first to third light emitting elements ED-1, ED-2, and ED-3 may be different from one another.

Referring to FIG. 7, the display device DD according to an embodiment may further include a light control layer PP. The light control layer PP may block external light incident to the display panel DP from outside the display device DD. The light control layer PP may block a part of the external light. The light control layer PP may perform a reflection prevention function minimizing reflection due to the external light.

In an embodiment illustrated in FIG. 7, the light control layer PP may include a color filter layer CFL. For example, the display device DD of an embodiment may further include the color filter layer CFL disposed on the light emitting elements ED-1, ED-2, and ED-3 of the display panel DP.

In the display device DD of an embodiment, the light control layer PP may include a base layer BL and a color filter layer CFL.

The base layer BL may provide a base surface on which the color filter layer CFL is disposed. The base layer BL may be a glass substrate, a metal substrate, a plastic substrate, etc. However, the embodiment is not limited thereto, and the base layer BL may include an inorganic layer, an organic layer, or a composite material layer.

The color filter layer CFL may include a light blocking unit BM and a color filter CF. The color filter may include filters CF-B, CF-G, and CF-R. For example, the color filter layer CFL may include a first filter CF-B transmitting a first color light, a second filter CF-G transmitting a second color light, and a third filter CF-R transmitting a third color light. For example, the first filter CF-B may be a blue filter, the second filter CF-G may be a green filter, and the third filter CF-R may be a red filter.

The filters CF-B, CF-G, and CF-R may each include a polymeric photosensitive resin and a pigment or dye. The first filter CF-B may include a blue pigment or dye, the second filter CF-G may include a green pigment or dye, and the third filter CF-R may include a red pigment or dye.

Embodiments are not limited thereto, and the first filter CF-B may not include a pigment or a dye. The first filter CF-B may include a polymer photosensitive resin, but not include a pigment or a dye. The first filter CF-B may be transparent. The first filter CF-B may be formed of a transparent photosensitive resin.

The light shielding part BM may be a black matrix. The light shielding part BM may include an organic light shielding material or an inorganic light shielding material containing a black pigment or dye. The light blocking unit BM may prevent light leakage, and separate boundaries between the adjacent filters CF-B, CF-G, and CF-R.

The color filter layer CFL may further include a buffer layer BFL. For example, the buffer layer BFL may be a protection layer protecting the filters CF-B, CF-G, and CF-R. The buffer layer BFL may be an inorganic material layer containing at least one inorganic material from silicon nitride, silicon oxide, and silicon oxynitride. The buffer layer BFL may be formed of a single layer or multiple layers.

In an embodiment illustrated in FIG. 7, the first filter CF-B of the color filter layer CFL is illustrated to overlap the second filter CF-G and the third filter CF-R, but embodiments are not limited thereto. For example, the first to third filters CF-B, CF-G, and CF-R may be separated by the light shielding part BM and may not overlap one another. In an embodiment, the first to third filters CF-B, CF-G, and CF-R may be disposed corresponding to the blue light emitting region PXA-B, the green light emitting region PXA-G, and the red light emitting region PXA-R, respectively.

Although not shown in FIG. 7 and the like, the display device DD according to an embodiment may include a polarizing layer (not shown) as a light control layer PP instead of the color filter layer CFL. The polarizing layer (not shown) may block external light provided to the display panel DP from the outside. The polarizing layer (not shown) may block a part of external light.

The polarizing layer (not shown) may reduce reflected light generated in the display panel DP by external light. For example, the polarizing layer (not shown) may function to block reflected light where light provided from outside the display device DD may be incident to the display panel DP and exits again. The polarizing layer (not shown) may be a circularly polarizer having a reflection preventing function or the polarizing layer may include a linear polarizer and a λ/4 phase retarder. The polarizing layer (not shown) may be disposed on the base layer BL to be exposed or the polarizing layer (not shown) may be disposed under the base layer BL.

Referring to FIG. 8, the display device DD-1 according to an embodiment may include a light conversion layer CCL disposed on a display panel DP-1. The display device DD-1 may further include a color filter layer CFL. The color filter layer CFL may be disposed between the base layer BL and the light conversion layer CCL.

The display panel DP-1 may be a light emitting display panel. For example, the display panel DP-1 may be an organic electroluminescence display panel or a quantum dot light emitting display panel.

The display panel DP-1 may include a base substrate BS, a circuit layer DP-CL provided on the base substrate BS, and a display element layer DP-EL1.

The display element layer DP-EL1 includes a light emitting element ED-a, and the light emitting element ED-a may include a first electrode EL1 and a second electrode EL2 facing each other, and layers OL disposed between the first electrode EL1 and the second electrode EL2. The layers OL may include a hole transport region HTR (FIG. 4), an emission layer EML (FIG. 4), and an electron transport region ETR (FIG. 4). An encapsulation layer TFE may be disposed on the light emitting element ED-a.

In the light emitting element ED-a, the same content as described with reference to FIG. 4 may be applied to the first electrode EL1, the hole transport region HTR, the electron transport region ETR, and the second electrode EL2. However, in the light emitting element ED-a included in the display panel DP-1 according to an embodiment, the emission layer may include a host and a dopant which may be organic electroluminescent materials or may include the quantum dot according to the embodiment as described above. In the display panel DP-1 according to an embodiment, the light emitting element ED-a may emit blue light.

The light conversion layer CCL may include banks BK disposed spaced apart from each other and light control parts CCP-B, CCP-G and CCP-R disposed between the banks BK. The banks BK may be formed including a polymer resin and a coloring additive. The banks BK may be formed including a light absorbing material, or formed including a pigment or a dye. For example, the banks BK may include a black pigment or a black dye to implement a black bank. In forming the black banks BK, carbon black, etc. may be used as the black pigment or the black dye, but the embodiment is not limited thereto.

The light conversion layer CCL may include a first light control part CCP-B which transmits the first light, a second light control part CCP-G including a fourth quantum dot QD-C2-a which converts the first light to the second light, and a third light control part CCP-R including a fifth quantum dot QD-C2-a which converts the first light to the third light. The second light may be light having a longer wavelength region than the first light, and the third light may be light having a longer wavelength region than the first light and the second light. For example, the first light may be blue light, the second light may be green light, and the third light may be red light. The content of the quantum dot described above may be the same with respect to at least one of the quantum dots QD-C2-a and QD-C2-a included in the light control parts CCP-B, CCP-G and CCP-R. For example, the same content of the quantum dot according to an embodiment as described above may be applied with respect to the fourth quantum dot QD-C2-a which converts the first light to the second light.

The light conversion layer CCL may further include a capping layer CPL. The capping layer CPL may be disposed on the light control parts CCP-B, CCP-G and CCP-R, and the banks BK. The capping layer CPL may serve to prevent penetration of moisture and/or oxygen (hereinafter, referred to as “moisture/oxygen”). The capping layer CPL may be disposed on the light control parts CCP-B, CCP-G and CCP-R to prevent the light control parts CCP-B, CCP-G and CCP-R from being exposed to moisture/oxygen. The capping layer CPL may include at least one inorganic layer.

The display device DD-1 according to an embodiment may include a color filter layer CFL disposed on the light conversion layer CCL, and the descriptions of FIG. 7 may be equally applied to the color filter layer CFL and the base layer BL.

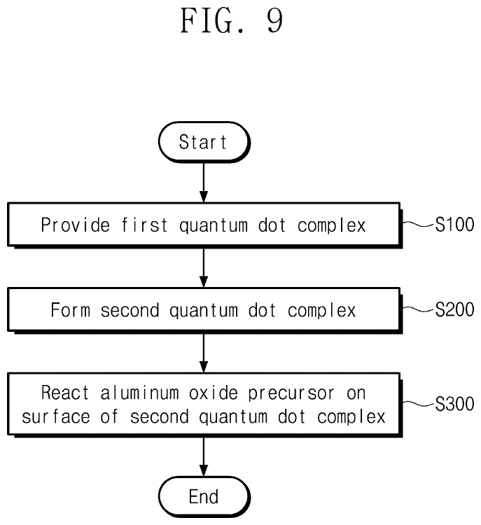

FIG. 9 is a flowchart of a method for preparing a quantum dot complex according to an embodiment.

Referring to FIG. 9, the method for preparing a quantum dot complex according to an embodiment may include providing a first quantum dot complex (S100), forming a second quantum dot complex (S200), and reacting an aluminum oxide precursor with the surface of the second quantum dot complex (S300).

The method for preparing a quantum dot complex according to an embodiment of the inventive concept may include providing a first quantum dot complex (S100). In providing of the first quantum dot complex (S100), forming a core may be performed first. The core may include a semiconductor compound selected from a Group II-VI compound, a Group III-VI compound, a Group I-III-VI compound, a Group III-V compound, a Group III-II-V compound, a Group IV-VI compound, a Group IV element, a Group IV compound, or any combination thereof. In an embodiment, the core may include a Group III-V compound or a Group I-III-VI compound. For example, the core may include InP or AgInGaS.

The core may be prepared by reacting a first precursor that is a cationic precursor and a second precursor that is an anionic precursor, which constitute the semiconductor compound. The first precursor and the second precursor may each independently include one or more precursors. For example, when the core includes InP, the core may be formed by reacting the first precursor including In with the second precursor including P.

The first precursor may include a Group I precursor, a Group II precursor, a Group III precursor, or a Group IV precursor, and may be a metal powder, a metal halide, a metal sulfate, a metal acetylacetonate, a metal hydroxide, a metal oxide, a metal nitrate, a metal carboxylate, an alkylated metal compound, or any combination thereof.

The Group I precursor may be one or more of silver halide, silver acetate, and silver nitrate. For example, the silver precursor may be silver iodide (AgI). However, embodiments are not limited thereto.

The Group II precursor may include a zinc precursor. The zinc precursor may be, for example, one or more of dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc peroxide, zinc perchlorate, and zinc sulfate. However, embodiments are not limited thereto.

The Group III precursor may be one or more of aluminum phosphate, aluminum acetylacetonate, aluminum chloride, aluminum fluoride, aluminum oxide, aluminum nitrate, aluminum sulfate, gallium nitride, gallium phosphide, gallium chloride, gallium acetylacetonate, gallium bromide, gallium chloride, gallium fluoride, gallium iodide, gallium nitrate hydrate, gallium sulfate, gallium sulfate hydrate, indium(III) acetylacetonate, indium(III) chloride, indium(III) iodide, indium(III) acetate, trimethyl indium, alkyl indium, aryl indium, indium(III) myristate, indium(III) myristate acetate, and indium(III) myristate 2 acetate. However, embodiments are not limited thereto. In an embodiment, the Group III precursor may include gallium.

The second precursor may include a Group VI precursor, or a Group V precursor, and may be a metal powder, a metal halide, a metal sulfate, a metal acetylacetonate, a metal hydroxide, a metal oxide, a metal nitrate, a metal carboxylate, an alkylated metal compound, or any combination thereof.

The Group V precursor may be one or more of alkyl phosphine, tris(trialkylsilyl)phosphine, tris(dialkylsilyl)phosphine, tris(dialkylamino)phosphine), arsenic oxide, arsenic chloride, arsenic sulfate, arsenic bromide, and arsenic iodide. However, embodiments are not limited thereto. The alkyl phosphine may be at least one of triethyl phosphine, tributyl phosphine, trioctyl phosphine, triphenyl phosphine, or tricyclohexyl phosphine.

The Group VI precursor may be one or more of sulfur, trialkylphosphine sulfide, trialkenylphosphine sulfide, alkylamino sulfide, alkenylamino sulfide, alkylthiol, selenium, trialkylphosphine selenide, trialkenylphosphine selenide, alkylamino selenide, alkenylamino selenide, trialkylphosphine telluride, trialkenylphosphine telluride, alkylamino telluride, and alkenylamino telluride. However, embodiments are not limited thereto.

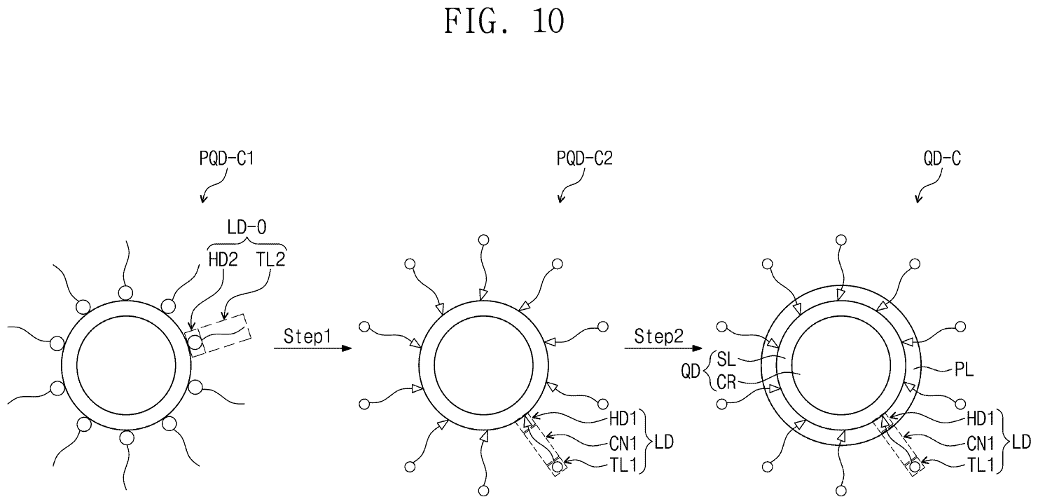

In an embodiment, before the reacting of the first precursor and the second precursor, preparing a mixture of the first precursor and the first ligand may be performed. A mixture may be provided by dispersing the first precursor in the first ligand. The first ligand may be a material that coordinates the surface of the first quantum dot complex PQD-C1 (see FIG. 10) to be prepared later and improves the dispersibility of the first quantum dot complex PQD-C1 (see FIG. 10) in a hydrophobic solvent.

A core may be formed by adding a second precursor to the mixture. The core may be formed by heat-treating the mixture after adding the second precursor to the mixture. For example, the second precursor is added to the mixture, and heat-treatment may be performed at 240° C. or higher. The core may be formed by reacting the first precursor with the second precursor. The first precursor may react with the second precursor to form a core CO (see FIG. 5).

In an embodiment, the first ligand may be any one of RCOOH, RNH₂, R₂NH, R₃N, RSH, RH₂PO, R₂HPO, R₃PO, RH₂P, R₂HP, R₃P, ROH, RCOOR′, RPO(OH)₂, and R₂POOH. R and R′ may correspond to the second tail part TL2 (see FIG. 10). R and R′ may each independently be a substituted or unsubstituted alkyl group having 1 to 30 carbon atoms, or a substituted or unsubstituted alkenyl group having 2 to 30 carbon atoms.

Examples of a first ligand may include methane thiol, ethane thiol, propane thiol, butane thiol, pentane thiol, hexane thiol, octane thiol, dodecane thiol, hexadecane thiol, octadecane thiol, benzyl thiol, methane amine, ethane amine, propane amine, butyl amine, pentyl amine, hexyl amine, octyl amine, dodecyl amine, hexadecyl amine, octadecyl amine, dimethyl amine, diethyl amine, dipropyl amine, oleylamine, trioctylamine, methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenylphosphine, triethylphosphine, ethyldiphenylphosphine, trioctylphosphine, trimethylphosphine oxide, methyldiphenylphosphine oxide, triethylphosphine oxide, ethyldiphenylphosphine oxide, trioctylphosphine oxide, and the like, but embodiments are not limited thereto. The first ligand may be one type of ligand or a mixture of two or more types of ligands.

In an embodiment, before the dispersing of the first precursor in the first ligand, dissolving the first precursor in an auxiliary solvent may be performed, but embodiments are not limited thereto. When the first precursor is preliminarily dissolved in the auxiliary solvent, the used auxiliary solvent may include at least one of hexane, toluene, chloroform, dimethyl sulfoxide, cyclohexylbenzene, hexadecane, or dimethyl formamide. However, embodiments are not limited thereto.

The method for preparing a quantum dot complex according to an embodiment may further include purifying the prepared core after the forming of the core. The purifying may be performed using chloroform, ethanol, acetone, or any combination thereof. However, embodiments are not limited thereto, and the purifying of the core in the method for preparing a quantum dot complex may be omitted depending on process conditions.

After the forming of the core, a shell may be formed. The shell may include a semiconductor compound selected from a Group II-VI compound, a Group III-VI compound, a Group I-III-VI compound, a Group III-V compound, a Group III-II-V compound, a Group IV-VI compound, a Group IV element, a Group IV compound, or any combination thereof. In an embodiment, the shell may include a Group II-V compound. The shell may be formed of a Group III-VI compound. For example, the shell may include ZnSeS.

The shell may be prepared by reacting a third precursor that is a cationic precursor and a fourth precursor that is an anionic precursor, which constitute the semiconductor compound. The third precursor and the fourth precursor may each be one or more. For example, when the shell includes ZnSeS, the shell may be formed by reacting the third precursor including Zn with two types of the fourth precursors each including Se and S. The same description of the first precursor as described above may be applied to the content of the third precursor. The same description of the second precursor as described above may be applied to the content of the fourth precursor.

The shell may be formed by adding the third precursor and the fourth precursor to a solution containing the core. The third precursor and the fourth precursor may be added to the solution in which the purified core is dispersed in a solvent, and heat-treatment may be performed. Accordingly, the core may react with the third precursor and the fourth precursor to form a shell surrounding the core. Accordingly, a first quantum dot complex PQD-C1 (see FIG. 10) including the quantum dot including the core, the shell surrounding the core, and the first ligand bonded on the surface of the quantum dot may be obtained.

The method for preparing a quantum dot complex according to an embodiment may further include, after the forming of the shell, purifying the quantum dot including the core and the shell surrounding the core. The purifying may be performed using chloroform, ethanol, acetone, or any combination thereof. However, embodiments are not limited thereto, and the purifying of the quantum dot in the method for preparing a quantum dot complex may be omitted depending on process conditions. When the shell included in the quantum dot has a multi-layered structure, the forming of the shell as described above may be performed at least two times, and the third precursor and the fourth precursor may be appropriately selected in consideration of the desired composition.

After the providing of the first quantum dot complex (S100), the forming of the second quantum dot complex may be performed. The forming of the second quantum dot complex may be exchanging the first ligand bonded to the first quantum dot complex with a second ligand including a hydrophilic group. After the forming of the first quantum dot complex, the first ligand bonded to the first quantum dot complex may be substituted with the second ligand. The second ligand corresponds to the ligand described above in FIG. 5, and the same content of the ligand as described above may be applied to the content of the second ligand.

The forming of the second quantum dot complex (S200) may include reacting the first quantum dot complex with the second ligand by adding the second ligand to a solution including the first quantum dot complex and the first solvent. A first mixture including the first quantum dot complex, the first solvent, and the second ligand may be prepared, and heating the first mixture at a first temperature may be performed. Accordingly, the first ligand bonded to the first quantum dot complex may be removed, and the second ligand may be bonded on the surface of the quantum dot to form a second quantum dot complex PQD-C2 (see FIG. 10). The first temperature is not limited, but may be, for example, about 50° C. to about 90° C.

The first solvent is not limited as long as it is able to dissolve the first quantum dot complex, but may include, for example, at least one of cyclohexyl acetate, hexane, toluene, chloroform, dimethyl sulfoxide, cyclohexylbenzene, hexadecane, or dimethyl formamide. However, embodiments are not limited thereto.

The method for preparing a quantum dot complex according to an embodiment may further include purifying the second quantum dot complex after the forming of the second quantum dot complex. The purifying may be performed using chloroform, ethanol, acetone, or any combination thereof. However, embodiments are not limited thereto, and the purifying of the quantum dot in the method for preparing a quantum dot complex may be omitted depending on process conditions.

After the forming of the second quantum dot complex (S200), the aluminum oxide precursor may be reacted with the surface of the second quantum dot complex (S300). In the reacting of the second quantum dot complex with the aluminum oxide precursor, putting a second mixture including the second quantum dot complex and a second solvent into the reactor and reacting the mixture at a second temperature, and injecting the aluminum oxide precursor into the reactor may be performed. The second mixture may be prepared by dispersing the second quantum dot complex in the second solvent. The second mixture may be put into the reactor and maintained at the second temperature. While maintaining the second temperature, the aluminum oxide precursor may be injected into the reactor and reacted for a certain period of time. In an embodiment, the second temperature is not limited, but may be, for example, room temperature to about 250° C. In the specification, the term “room temperature” may mean a temperature of about 15° C. to about 30° C., for example, a temperature of about 25° C.

The second solvent is not limited as long as it is able to dissolve the second quantum dot complex, but may include, for example, at least one of cyclohexyl acetate, hexane, toluene, chloroform, dimethyl sulfoxide, cyclohexylbenzene, hexadecane, or dimethyl formamide. However, embodiments are not limited thereto.

A content of the aluminum oxide precursor used in the reacting of the aluminum oxide precursor with the surface of the second quantum dot complex (S300) may be equal to or greater than about 1.0 mM. In an embodiment, the aluminum oxide precursor content may be in a range of about 1.0 mM to about 4.0 mM. For example, while the second mixture including the second quantum dot complex and the second solvent is put into the reactor and maintained at the second temperature, in a range of about 1.0 mM to about 4.0 mM of the aluminum oxide precursor may be injected into the reactor. However, embodiments are not limited thereto, and the aluminum oxide precursor content may be appropriately adjusted according to the precursor material used, the thickness of the desired protective layer, and the like. In an embodiment, the reacting of the aluminum oxide precursor with the surface of the second quantum dot complex (S300) may further include injecting oxygen gas into the reactor after the injecting of the aluminum oxide precursor into the reactor. The injecting of oxygen may react the aluminum oxide precursor with oxygen. However, embodiments are not limited thereto, and the injecting of oxygen according to kinds of precursors may be omitted.

In an embodiment, the aluminum oxide precursor may be represented by Formula A:

Al(R₄)₃ [Formula 1]

In Formula A, R₄ may be a halogen atom, a substituted or unsubstituted oxy group, or a substituted or unsubstituted alkyl group having 1 to 20 carbon atoms. For example, R₄ may be a halogen atom, a substituted or unsubstituted isopropoxide group, or a substituted or unsubstituted methyl group.

In an embodiment, the aluminum oxide precursor may be provided in a thiolated form. For example, the aluminum oxide precursor may include an Al element and an alkoxy group linked to the Al element, and at least one of the alkoxy groups linked to the Al element may be substituted with a thiol group. The thiolated aluminum oxide precursor may be formed by reacting a thiol-based compound with an aluminum oxide. The thiol-based compound may be, for example, 1-dodecanethiol, but embodiments are not limited thereto. In an embodiment, the aluminum oxide precursor may be represented by Formula B:

Al(OR₅)₃₋ₙ(SR₆)ₙ [Formula B]

In Formula B, R₅ and R₆ may each independently be a substituted or unsubstituted alkyl group having 1 to 20 carbon atoms. In an embodiment, R₅ may be a substituted or unsubstituted isopropyl group. For example, R₅ may be an unsubstituted isopropyl group. In an embodiment, R₆ may be a substituted or unsubstituted dodecyl group. For example, R₆ may be an unsubstituted dodecyl group.

In Formula B, n may be an integer from 0 to 3.

In an embodiment, the aluminum oxide precursor may include at least one of trimethylaluminum, aluminum isopropoxide, and aluminum chloride.

In the reacting of the aluminum oxide precursor with the surface of the second quantum dot complex (S300), the aluminum oxide precursor may react with the surface of the second quantum dot complex to form a protective layer PL (see FIG. 10) including the aluminum oxide on the surface of the quantum dot. For example, the aluminum oxide may be grown on the surface of the quantum dot to form a protective layer having a certain thickness. The protective layer may be formed to surround the surface of the quantum dot. The protective layer may be formed to surround the shell provided on the surface of the quantum dot. In the process of forming the protective layer, the second ligand bonded on the surface of the quantum dot may maintain the state of being bonded on the surface of the second quantum dot complex.

As the protective layer is formed, the second ligand may be stably bonded on the surface of the quantum dot. The protective layer may serve to fix the second ligand on the surface of the quantum dot. Accordingly, the migration, detachment, etc. of the second ligand is prevented in a subsequent process, and thus the stability of the quantum dot may be further improved.

In an embodiment, the second ligand bonded on the surface of the quantum dot may maintain the state in which the second ligand is bonded on the surface of the second quantum dot complex. The second ligand bonded to the quantum dot may be bonded to the aluminum oxide included in the protective layer. For example, the second ligand may form a bond with the Al atom included in the protective layer. As the second ligand forms a bond with the aluminum oxide, the second ligand may be stably fixed on the surface of the quantum dot. However, embodiments are not limited thereto.

FIG. 10 is a view illustrating one step of the method for preparing a quantum dot according to an embodiment. FIG. 10 illustrates forming a second quantum dot complex and reacting the surface of the second quantum dot complex with an aluminum oxide precursor in the method for preparing a quantum dot according to an embodiment. In the description of FIG. 10, the duplicated features which have been described in FIGS. 5 and 9 will not be described again, and their differences will be described.

In FIG. 10, “Step 1” indicates the forming of the second quantum dot complex. In FIG. 10, “Step 2” indicates the reacting of the surface of the second quantum dot complex with the aluminum oxide precursor.

Referring to Step 1, a first quantum dot complex PQD-C1 may be provided. The same description of the first quantum dot complex as described above in FIG. 9 may be applied to the first quantum dot complex PQD-C1. For example, the first quantum dot complex PQD-C1 may include a quantum dot QD and a first ligand LD-O bonded on the surface of the quantum dot QD. The first ligand LD-O may include a second head part HD2 bonded on the surface of the quantum dot QD and a second tail part TL2 linked to the second head part HD2. In the specification, the first ligand LD-O may be referred to as an organic ligand.

The second head part HD2 may include one of a carboxyl group, an amine group, a thiol group, a phosphine group, a phosphonate group, a phosphate group, a phosphine oxide group, and a carboxylic acid group.

The second tail part TL2 may be linked to the second head part HD2. The second head part HD2 may be bonded on the surface of the quantum dot QD, and the second tail part TL2 may be exposed to the outside of the quantum dot QD. The second tail part TL2 may be a substituted or unsubstituted alkyl group having 1 to 30 carbon atoms, or a substituted or unsubstituted alkenyl group having 2 to 30 carbon atoms.

In order to exchange the first ligand LD-O bonded on the surface of the quantum dot QD with the second ligand LD including a hydrophilic group, the first quantum dot complex PQD-C1 may be reacted with the second ligand LD. The reacting of the first quantum dot complex PQD-C1 with the second ligand LD may remove the first ligand LD-O bonded on the surface of the quantum dot QD and bonding the second ligand LD on the surface of the quantum dot QD. Accordingly, the second quantum dot complex PQD-C2 including the quantum dot QD and the second ligand LD bonded on the surface of the quantum dot QD may be formed.

Referring to Step 2, reacting the surface of the second quantum dot complex PQD-C2 with an aluminum oxide precursor may be performed. The reacting of the surface of the second quantum dot complex PQD-C2 with the aluminum oxide precursor may grow the aluminum oxide on the surface of the quantum dot QD. The aluminum oxide may be derived from the aluminum oxide precursor. When the reaction of the second quantum dot complex PQD-C2 with the aluminum oxide precursor is completed, a protective layer PL having a certain thickness from the surface of the quantum dot QD may be formed.

The quantum dot may have reduced luminous efficiency because charge carriers are trapped due to dangling bonds on the surface, atomic vacancy, and the like. The presence of dangling bonds and atomic vacancy in the quantum dots may cause non-radiative recombination, thereby reducing the luminous efficiency. As a method for passivating surface defects of the quantum dot, a method for introducing an organic ligand in the synthesis of quantum dots may be used. A long-chain organic ligand such as oleic acid or oleylamine may have an effect of effectively passivating surface defects of the quantum dot while uniformly dispersing the quantum dot in a hydrophobic solvent. However, when quantum dots protected by organic ligands are mixed in a hydrophilic solvent in order to make the quantum dots ink, the affinity between the hydrophobic organic ligands and the hydrophilic solvent is low, and thus the stability of the quantum dots may be deteriorated, and the aggregation of the quantum dots may be caused. When the hydrophobic organic ligand is exchanged with the hydrophilic ligand through the ligand-exchange process, the quantum dot protected with the hydrophilic ligand may have improved stability due to high affinity with the hydrophilic solvent, but there may be a limitation in that the luminous efficiency is deteriorated due to surface defects caused by the migration, detachment, etc. of the ligands.

According to an embodiment, the method for preparing a quantum dot complex includes exchanging an organic ligand bonded on the surface of the quantum dot with a ligand containing a hydrophilic group, and reacting the surface of the quantum dot containing the hydrophilic group with the aluminum oxide precursor, and thus may have an effect of strongly bonding the ligand on the surface of the quantum dot. Accordingly, the quantum dot complex prepared by the method for preparing a complex of an embodiment may exhibit excellent quantum yield characteristics and improved stability. Since the organic ligand is exchanged with the ligand containing a hydrophilic group, it may be possible to improve dispersion stability of the quantum dots even if a hydrophilic solvent is used in a subsequent process of making the quantum dot ink.

Hereinafter, with reference to Examples and Comparative Examples, the quantum dot according to an embodiment of the inventive concept will be described in detail. Examples and Comparative Examples described below are only illustrations to assist the understanding of the embodiments, and the scope of the embodiments is not limited thereto.

### EXAMPLES AND COMPARATIVE EXAMPLES

### 1. Preparation of Quantum Dot Complex

### 1) Example 1

### Step 1: Preparation of InP Core

Indium acetate (10 mmol), zinc acetate (5 mmol), and oleic acid (40 mmol) were added to a three-neck flask together with ODE and mixed, and the resultant mixture was degassed and stirred at about 120° C. for about 60 minutes and oxygen and moisture therein were removed to form a reaction solution. TMSP (8 mmol) was added to the reaction solution in an argon atmosphere, and the resultant solution was heated up to about 300° C., and reacted for a certain period of time to synthesize an InP core.

### Step 2: Preparation of InP/ZnSeS of Core/Shell Quantum Dot

The InP core was purified with a mixed solution of toluene and acetone and dissolved in toluene. Zinc oleate (26 mmol), trioctylphosphine selenide (10.2 mmol), trioctylphosphine sulfide (8 mmol), and trioctylamine were added thereto and reacted at greater than or equal to about 320° C. for about 1 hour or more to form a ZnSeS shell on the surface of the InP core, thereby synthesizing InP/ZnScS quantum dots.

### Step 3: Substitution of Ligand

The InP/ZnSeS quantum dots were purified and dissolved in cyclohexyl acetate to prepare 34 wt % of a QD solution. A hydrophilic ligand for ligand exchange (about 50-70% based on the first particles) was added to the QD solution to react at about 70° C. for about 1 hour. The QD solution was purified using hexane, and the solid InP/ZnSeS quantum dots were separated.

### Step 4: Formation of Protective Layer

The InP/ZnSeS quantum dots separated in step 3 above were dissolved in chloroform (anhydrous), 2.4 mM of trimethylaluminum (in octane) was slowly added dropwise at about 60° C., and O₂ was slightly flowed.

### 2) Example 1-1

A quantum dot complex was synthesized in the same manner as in Example 1, except that the concentration of trimethylaluminum was 1.2 mM.

### 3) Example 1-2

A quantum dot complex was synthesized in the same manner as in Example 1, except that the concentration of trimethylaluminum was 3.6 mM.

### 4) Example 2

The InP/ZnSeS quantum dots separated in step 3 above were dissolved in aluminum isopropoxide (in DDT-dodecanethiol 3 mol %, 8 mL), and stirred at about 200° C. for about 2 hours.

### 5) Example 3

The InP/ZnSeS quantum dots separated in step 3 above were dissolved in chloroform (anhydrous), 2.4 mM of aluminum chloride (in ethanol) was mixed therewith at room temperature, and stirred for about 1 hour.

### 6) Comparative Example 1

A quantum dot complex was synthesized in the same manner as in Example 1, except that steps 3 and 4 were omitted in Example 1.

### 7) Comparative Example 2

A quantum dot complex was synthesized in the same manner as in Example 1, except that step 4 was omitted in Example 1.

### 8) Comparative Example 3

A quantum dot complex was synthesized in the same manner as in Example 1, except that the order of steps 3 and 4 was changed in Example 1.

### 2. Preparation of Photoconversion Pattern

The quantum dot complexes prepared in Examples 1 to 3, and Comparative Examples 1 and 2 were each mixed with 1,6-hexanediol diacrylate (HDDA) to prepare a quantum dot complex composition, and a photoconversion single film was prepared using the prepared quantum dot complex composition. The prepared quantum dot complex composition was spin-coated on an organic substrate to obtain a 10 μm-thick film. A 3,000 Å-thick capping layer containing SiNₓ was formed on the obtained film by sputtering to form a photoconversion pattern.

Table 1 shows photoluminescence quantum yield (PLQY), external quantum efficiency (EQE), and a maintenance rate of photoconversion efficiency according to Examples and Comparative Examples. For the photoluminescence quantum yield, the surface-substituted quantum dots obtained in Examples 1 to 3 and Comparative Examples 1 and 2 were each separated and dispersed in chloroform to prepare a quantum dot dispersion, and the photoluminescence quantum yield (PLQY) of the quantum dot dispersion was measured by using QE-2100 equipment made by Otsuka Electronics, Co., Ltd. The external quantum efficiency at a current density of 1,000 cd/m² was measured using QE-2100 equipment in order to evaluate the characteristics of the photoconversion patterns prepared in Examples 1 to 3 and Comparative Examples 1 and 2.

Excitation light having a wavelength of about 460 nm was emitted at a light amount of 60 mW/cm² for about 500 hours with respect to the photoconversion patterns prepared in the Examples and Comparative Examples. The photoconversion efficiency was measured to calculate a maintenance rate of the photoconversion efficiency after about 500 hours compared to the initial measurement value, and the results are shown in Table 1. In Table 1, the photoconversion efficiency before emitting excitation light to the quantum dots is measured, and when the measured value is referred to as an initial photoconversion efficiency, the degree of maintenance of the initial photoconversion efficiency is converted into %, and the conversion value is the maintenance rate (%) of the photoconversion efficiency. The maintenance rate of the photoconversion efficiency may be calculated by Equation 1:

$$Maintenance rate of photoconversion efficiency = ( {E}_{1} / {E}_{2} ) \times 100 \qquad [ Equation 1 ]$$

In Equation 1, E₂ is a quantum yield value measured before emitting the excitation light, and E₁ is a quantum yield value measured after emitting, to the quantum dot, excitation light having a wavelength of about 460 nm with a light amount of about 60 mW/cm² for about 500 hours.

For the photoconversion efficiency, the photoconversion rate was measured with QE-2100 equipment, and measured by calculating the area of emission peak of the converted light to the area of absorption peak of blue light. For example, the photoconversion efficiency (PCE) of Examples and Comparative Examples may be calculated by Equation 2:

$$PCE = ( {A}_{2} / {A}_{1} ) \times 100 \qquad [ Equation 2 ]$$

In Equation 2, A₁ represents the area of absorption spectrum of blue light, and A₂ represents the area of emission spectrum of the converted light. For example, A₁ may correspond to the area of absorption peak with respect to the blue light absorbed by the quantum dots. A₂ may correspond to the area of emission peak with respect to the converted light by the quantum dots.

TABLE 1

| | | | Maintenance rate (%) |
|---|---|---|---|
| | Solution | External quantum | of photoconversion |
| Division | PLQY (%) | efficiency (%) | efficiency |
| Example 1 | 83.5 | 27.02 | 101 |
| Example 2 | 86.8 | 28.23 | 51 |
| Example 3 | 88.9 | 29.23 | 42 |
| Comparative | 88.0 | X | X |
| Example 1 | | No dispersion | No dispersion |
| Comparative | 89.2 | 29.43 | 31 |
| Example 2 | | | |
| Comparative | 86.0 | X | X |
| Example 3 | | No dispersion | No dispersion |

Referring to the results of Table 1, it may be seen that Examples prepared by the method for preparing a quantum dot complex according to an embodiment exhibit photoluminescence quantum yields and external quantum efficiencies similar to the Comparative Examples, and also have maintenance rates of photoconversion efficiency higher than the Comparative Examples. When Examples 1 to 3 are each compared with Comparative Example 1, it may be seen that the quantum yield of Comparative Example 1 is similar to that of Examples 1 to 3, but the pattern could not be prepared due to low dispersibility in a process of making the quantum dot ink. The quantum dot complex of Comparative Example 1 corresponds to the case in which the exchanging of the ligand corresponding to step 3 and the forming of the protective layer corresponding to step 4 are not performed as compared with the quantum dot complex of Example. In the case of the quantum dot complex formed without the process of exchanging the ligand with the hydrophilic ligand as in Comparative Example 1, the affinity with the hydrophilic solvent may be deteriorated due to the hydrophobic organic ligands present on the surface of the quantum dot, and thus the dispersibility of the particles may be deteriorated. Accordingly, the aggregation of the quantum dot complexes occurs in the process of making the quantum dot complex ink, thereby making it difficult to form a single film.

When the Examples are compared with Comparative Example 2, the quantum dot complexes of the Examples correspond to the case in which both ligands containing a hydrophilic group and a protective layer are formed on the surface of the quantum dot having a structure of InP/ZnSeS. The quantum dot complex of Comparative Example 2 has a same structure as the quantum dot of Example, except that the quantum dot complex of Comparative Example 2 does not include a protective layer containing an aluminum oxide. The quantum dot complex of Comparative Example 2 may be in the state before the surface of the second quantum dot complex reacts with the aluminum oxide precursor in the method for preparing the quantum dot complex according to an embodiment.

It may be seen that the quantum yields and the external quantum efficiencies of the Examples and Comparative Example 2 show similar values. However, it may be seen that in Comparative Example 2, the maintenance rate of the photoconversion efficiency after emitting light for about 500 hours was about 31%, whereas in the Examples, the maintenance rate of the photoconversion efficiency after emitting light for about 500 hours was greater than or equal to about 42%, showing a higher value than that of Comparative Example 2. For example, it can be seen that the quantum dot complex formed by the method for preparing a quantum dot in the Examples exhibits high luminous efficiency similar to that of the quantum dot of Comparative Example 2 that does not include the protective layer containing the aluminum oxide, as well as exhibits the maintenance rate of photoconversion efficiency higher than that of Comparative Example 2. The quantum dot complexes of the Examples each include the protective layer to effectively protect the quantum dot, and may prevent the migration, the detachment, etc. of the ligands to exhibit a high level of photostability.

When Example is compared with Comparative Example 3, it may be seen that the quantum yield of Comparative Example 3 is similar to that of Example, but the pattern could not be prepared due to low dispersibility in a process of making the quantum dot ink. The quantum dot complex of Comparative Example 3 corresponds to the case in which the forming of the protective layer corresponding to step 4 is performed first and the exchanging of the first ligand with the second ligand is performed as compared with the quantum dot complex of Example. When the protective layer is formed on the quantum dot to which the first ligand is bonded without the ligand-exchange process, the bonding strength between the first ligand and the surface of the quantum dot is increased by the protective layer, thereby reducing the ligand exchange rate. Accordingly, in the process of making the quantum dot complex ink due to the first ligand fixed on the surface of the quantum dot, the aggregation of the quantum dot complex may occur due to low affinity of the quantum dot complex to the hydrophilic solvent, and thus, it may be difficult to form a single film. In the Examples, the first ligand is exchanged with the second ligand, and the protective layer is formed, so that the dispersion stability of the quantum dot complex may be improved, thereby improving the process reliability.

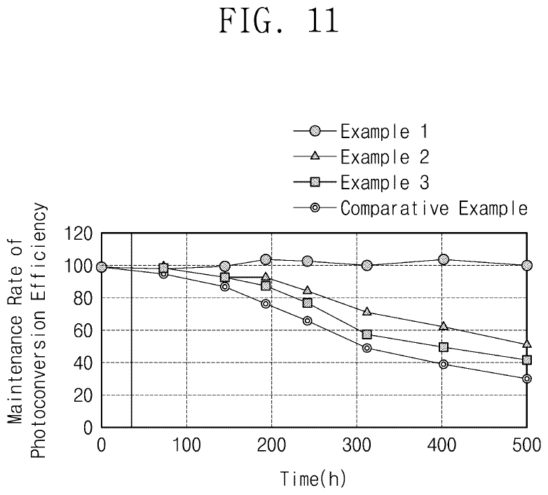

FIG. 11 is a graph showing the measurement of a maintenance rate of photoconversion efficiency over time of a photoconversion pattern according to the Examples and Comparative Examples. Excitation light having a wavelength of about 460 nm was emitted at a light amount of 60 mW/cm² for about 500 hours with respect to the photoconversion patterns prepared in the Examples and Comparative Examples, and the photoconversion efficiency over time was measured to calculate a maintenance rate of the photoconversion efficiency for each time compared to the initial measurement value, and the results are shown in FIG. 11.

Referring to FIG. 11, it may be seen that the maintenance rate of photoconversion efficiency of the photoconversion pattern of the Examples using the quantum dot complex according to an embodiment shows a value higher than that of the Comparative Examples. For example, it may be seen that in the case of the photoconversion pattern prepared according to Example 1, the maintenance rate of photoconversion efficiency was measured close to 100% at each time. For example, it may be seen that the photoconversion pattern of Example 1 did not decrease in efficiency after emitting light and was maintained at a certain level. In comparison, it may be seen that the maintenance rate of photoconversion efficiency of the photoconversion pattern of the Comparative Examples using the quantum dot complex of the Comparative Examples gradually decreases from about 200 hours after the light is emitted, and the photoconversion efficiency significantly decreases to about 31% after about 500 hours.

Table 2 shows the results of evaluation of the quantum dot complexes of the Examples and the photoconversion pattern prepared using the quantum dot complexes. The characteristics according to the concentration of the aluminum oxide precursor when the protective layer was formed were evaluated, and the results are shown in Table 2 below. In Table 2, the photoluminescence quantum yield, the external quantum efficiency, and the maintenance rate of photoconversion efficiency of the Examples were measured in the same manner as the method described in Table 1 above.

TABLE 2

| | | | Maintenance rate (%) |
|---|---|---|---|
| | Solution | External quantum | of photoconversion |
| Division | PLQY (%) | efficiency (%) | efficiency |
| Example 1 | 83.5 | 27.02 | 101 |
| Example 1-1 | 84.8 | 28.25 | 88 |
| Example 1-2 | 78.9 | 25.73 | 90 |

Referring to the results of Tables 1 and 2, it may be seen that Examples 1, 1-1, and 1-2 prepared by the method for preparing a quantum dot complex according to an embodiment of the inventive concept exhibit photoluminescence quantum yields and external quantum efficiencies similar to the Comparative Examples, and also have maintenance rates of photoconversion efficiency higher than the Comparative Examples.

The quantum dot according to an embodiment may include a shell doped with a Group IIIA oxide, and thus may exhibit high quantum yield and excellent stability.

The method for preparing a quantum dot according to an embodiment may provide the quantum dot exhibiting high quantum yield and excellent stability.

The display device according to an embodiment may include the quantum dot exhibiting high quantum yield and excellent stability, and thus may exhibit improved luminous efficiency characteristics.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A quantum dot complex comprising:
a quantum dot;
a ligand which is bonded on a surface of the quantum dot and includes a hydrophilic group; and
a protective layer which is bonded on the surface of the quantum dot and includes an aluminum oxide.

2. The quantum dot complex of claim 1, wherein the hydrophilic group is a polyethylene glycol group or a (meth)acrylate group.

3. The quantum dot complex of claim 1, wherein
the ligand comprises:
a first head part bonded on the surface of the quantum dot;
a first linking part linked to the first head part; and
a first tail part linked to the first linking part, and
at least one of the first linking part and the first tail part includes the hydrophilic group.

4. The quantum dot complex of claim 3, wherein the first head part is a thiol group, a dithioic acid group, a phosphine group, a catechol group, an amine group, or a carboxylic acid group.

5. The quantum dot complex of claim 1, wherein the ligand is a monodentate ligand or a bidentate ligand.

6. The quantum dot complex of claim 1, wherein the ligand is represented by Formula 1-1 or Formula 1-2: 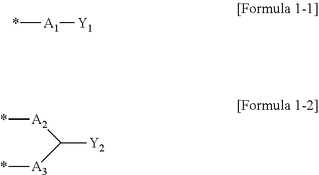
wherein in Formula 1-1 and Formula 1-2,
A₁ to A₃ are each independently O, S, or NH,
Y₁ and Y₂ are each independently a moiety represented by one of Formula 2-1 to Formula 2-3, and
*---- is a position linked on the surface of the quantum dot; 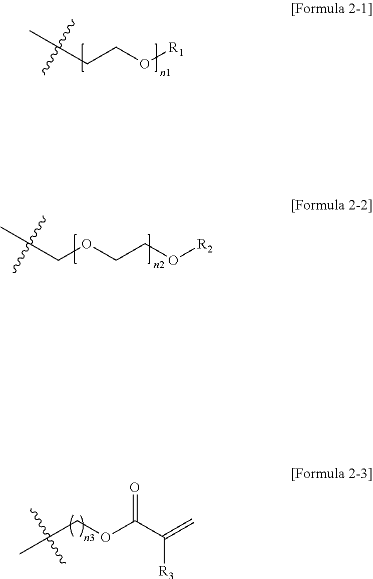
wherein in Formula 2-1 to Formula 2-3,
R₁ and R₂ are each independently a substituted or unsubstituted oxy group, a substituted or unsubstituted thiol group, a substituted or unsubstituted alkyl group having 1 to 20 carbon atoms, or a substituted or unsubstituted alkenyl group having 2 to 20 carbon atoms,
R₃ is a hydrogen atom or a substituted or unsubstituted methyl group,
n1 to n3 are each independently an integer from 1 to 20, and 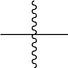
is a position linked to Formula 1-1 or Formula 1-2.

7. The quantum dot complex of claim 1, wherein
the quantum dot comprises a core, and a shell surrounding the core, and
the ligand and the protective layer are each bonded on the surface of the shell.

8. The quantum dot complex of claim 7, wherein
the core comprises first semiconductor nanocrystals,
the shell comprises second semiconductor nanocrystals that are different from the first semiconductor nanocrystals, and
the first semiconductor nanocrystals and the second semiconductor nanocrystals are each independently a Group II-VI compound, a Group III-VI compound, a Group I-III-VI compound, a Group III-V compound, a Group III-II-V compound, a Group IV-VI compound, a Group IV element, a Group IV compound, or a combination thereof.

9. The quantum dot complex of claim 7, wherein the core comprises InP or AgInGaS.

10. The quantum dot complex of claim 1, wherein the protective layer surrounds the surface of the quantum dot.

11. A method for preparing a quantum dot complex comprising:
providing a first quantum dot complex including a quantum dot, and a first ligand bonded on a surface of the quantum dot;
exchanging the first ligand bonded to the first quantum dot complex with a second ligand including a hydrophilic group to form a second quantum dot complex; and
reacting an aluminum oxide precursor with a surface of the second quantum dot complex.

12. The method of claim 11, wherein the aluminum oxide precursor comprises at least one of trimethylaluminum, aluminum isopropoxide, and aluminum chloride.

13. The method of claim 11, wherein a protective layer which covers the second quantum dot complex is formed by reacting the aluminum oxide precursor with the surface of the second quantum dot complex.

14. The method of claim 11, wherein the forming of the second quantum dot complex comprises heating a first mixture including the first quantum dot complex, a first solvent, and the second ligand at a first temperature.

15. The method of claim 11, wherein the reacting of the aluminum oxide precursor with the surface of the second quantum dot complex comprises:
putting a second mixture including the second quantum dot complex and a second solvent into a reactor and reacting the second mixture at a second temperature; and
injecting the aluminum oxide precursor into the reactor.

16. The method of claim 15, wherein the reacting of the aluminum oxide precursor with the surface of quantum dot further comprises:
injecting oxygen into the reactor after the injecting of the aluminum oxide precursor.

17. The method of claim 11, wherein the second ligand is represented by Formula 1-1 or Formula 1-2: 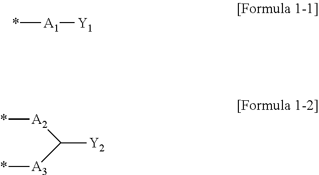
wherein in Formula 1-1 and Formula 1-2,
A₁ to A₃ are each independently O, S, or NH,
Y₁ and Y₂ are each independently a moiety represented by one of Formula 2-1 to Formula 2-3, and
*---- is a position linked on the surface of the quantum dot; 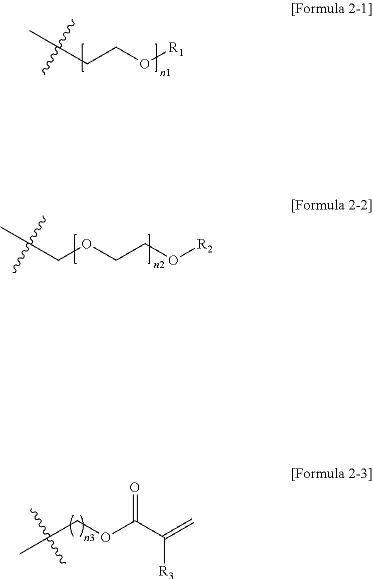
wherein in Formula 2-1 to Formula 2-3,
R₁ and R₂ are each independently a substituted or unsubstituted oxy group, a substituted or unsubstituted thiol group, a substituted or unsubstituted alkyl group having 1 to 20 carbon atoms, or a substituted or unsubstituted alkenyl group having 2 to 20 carbon atoms,
R₃ is a hydrogen atom or a substituted or unsubstituted methyl group,
n1 to n3 are each independently an integer from 1 to 20, and 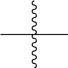
is a position linked to Formula 1-1 or Formula 1-2.

18. The method of claim 11, wherein
a maintenance rate of photoconversion efficiency of the quantum dot complex is equal to or greater than about 90%, and
the maintenance rate of photoconversion efficiency is expressed by Equation 1:
$$Maintenance rate of photoconversion efficiency = ( {E}_{1} / {E}_{2} ) \times 100 \qquad [ Equation 1 ]$$
wherein in Equation 1,
E₁ is a quantum yield measured after emitting, to the quantum dot, excitation light having a wavelength of about 460 nm with a light amount of about 60 mW/cm² for about 500 hours, and
E₂ is a quantum yield measured before emitting the excitation light.

19. A display device comprising:
a display panel; and
a light conversion layer which is disposed on the display panel and comprises a plurality of light control parts, wherein
at least one of the plurality of light control parts comprises a quantum dot complex, and
the quantum dot complex comprises:
a quantum dot;
a ligand which is bonded on a surface of the quantum dot and includes a hydrophilic group; and
a protective layer which is bonded on the surface of the quantum dot and includes an aluminum oxide.

20. The display device of claim 19, wherein
the display panel comprises a light emitting element that generates a first light, and
the light conversion layer comprises:
a first light control part that transmits the first light;
a second light control part that converts the first light to second light; and
a third light control part that converts the first light to third light.
